(19) United States
(12) Patent Application Publication
(10) Pub. No.: US 2025/0294881 A1
(43) Pub. Date: Sep. 18, 2025

(54) ACTIVE MATRIX SUBSTRATE AND LIQUID CRYSTAL DISPLAY DEVICE

(71) Applicant: Sharp Display Technology Corporation, Kameyama City (JP)

(72) Inventors: Atsushi HACHIYA, Kameyama City (JP); Hiroaki FURUKAWA, Kameyama City (JP); Yuhichi SAITOH, Kameyama City (JP)

(21) Appl. No.: 19/075,874

(22) Filed: Mar. 11, 2025

(30) Foreign Application Priority Data
Mar. 13, 2024 (JP) 2024-039212

(51) Int. Cl. H10D 86/40; G02F 1/1362; G02F 1/1368

(52) U.S. Cl. CPC H10D 86/451; G02F 1/136286; G02F 1/1368; H10D 86/441

(57) ABSTRACT

An active matrix substrate includes first TFTs located in pixel regions, respectively, a first flattened layer covering the first TFTs, pixel electrodes provided on the first flattened layer, and first connection electrodes located under the first flattened layer, each of the first connection electrodes electrically connecting an oxide semiconductor layer and each of the pixel electrodes. The first flattened layer has pixel contact holes formed so as to expose portions of first connection electrodes, respectively. The active matrix substrate further includes second connection electrodes, each of the second connection electrodes electrically connecting each of the first connection electrodes and each of the pixel electrodes, and being in contact with each of the first connection electrodes in each of the pixel contact holes, and second flattened layers formed such that the pixel contact holes are filled with the second flattened layers, respectively. An equivalent circle diameter of a bottom face of each of the pixel contact holes is three times or more and five times or less an equivalent circle diameter of an upper face of each of the second flattened layers.

### CROSS-REFERENCE TO RELATED APPLICATIONS

This application claims the benefit of priority to Japanese Patent Application Number 2024-039212 filed on Mar. 13, 2024. The entire contents of the above-identified application are hereby incorporated by reference.

### BACKGROUND

### Technical Field

The disclosure relates to an active matrix substrate and a liquid crystal display device.

At present, a liquid crystal display device including an active matrix substrate is being widely used for various purposes. The active matrix substrate includes switching elements for pixel regions, respectively. An active matrix substrate including thin film transistors (TFTs) as the switching elements is referred to as a TFT substrate.

The TFT substrate includes TFTs and pixel electrodes provided in pixel regions, respectively, gate wiring lines for supplying gate signals to the TFTs, source wiring lines for supplying source signals to the TFTs, and the like. A gate electrode, a source electrode, and a drain electrode of the TFT are respectively electrically connected to the gate wiring line, the source wiring line, and the pixel electrode. The TFTs are covered with an interlayer insulating layer.

A flattened layer (organic insulating film) for flattening a surface may be formed on the interlayer insulating layer. Forming the flattened layer also reduces load capacitance (parasitic capacitance), thereby reducing power consumption. As a material for the flattened layer, a photosensitive resin material is used in many cases. When the flattened layer is formed, the pixel electrode is provided on the flattened layer and is connected to the drain electrode of the TFT in a contact hole formed in the flattened layer and the like.

### SUMMARY

In order to obtain a sufficient flattening effect and a sufficient effect of reducing load capacitance, a photosensitive resin material is applied thickly (e.g., in a thickness of several μm) when forming the flattened layer. Therefore, in order to form the contact hole so as to reliably expose a lower layer of the flattened layer, it is necessary to apply sufficient exposure energy to the photosensitive resin material during exposure so as to sufficiently expose the photosensitive resin material in a depth direction. To be specific, exposure is performed by increasing an exposure time or increasing a size of a mask pattern so as to more reliably expose a region to be removed by photolithography. Therefore, in order to stably form the contact hole (so as to more reliably expose the lower layer of the flattened layer), an only option is to increase a finished diameter of the contact hole.

An alignment state of liquid crystal molecules is disordered in the vicinity of the contact hole, thereby causing light leakage, and thus the contact hole causes decreases in contrast ratio and display quality. Providing a light blocking layer that blocks light from reaching the vicinity of the contact hole can suppress deteriorations in contrast ratio and display quality, but an area in the pixel region that contributes to display is reduced by an area of the light blocking layer, resulting in a decrease in transmittance (light usage efficiency). In high-resolution (e.g., 1000 ppi or higher) liquid crystal display devices such as liquid crystal display devices for head-mounted displays, a proportion of the contact hole in the pixel region is large, resulting in the large decrease in transmittance described above.

JP 2017-187714 A discloses a configuration that can make a contact hole formed in a flattened layer (organic insulating film) shallower. In the configuration disclosed in JP 2017-187714 A, an electrode (referred to as a “metal portion” in JP 2017-187714 A) that electrically connects a polysilicon semiconductor layer, which is an active layer of a TFT, and a pixel electrode is raised by a structure referred to as a “pedestal portion” provided directly under the electrode, whereby a contact hole formed in a flattened layer can be made shallower.

However, when a complicated structure such as that disclosed in JP 2017-187714 A is actually formed in a pixel, light leakage is a concern, so that it is considered necessary to block light from reaching the vicinity of the pedestal portion by some method. Therefore, even when the configuration disclosed in JP 2017-187714 A is adopted, it is difficult to significantly improve transmittance (significantly improve aperture ratio). In addition, various additional steps for forming the pedestal portion increase process load, which causes a problem of increased manufacturing cost for the TFT substrate.

The disclosure has been made in consideration of the above-mentioned problems, and an object of the disclosure is to provide an active matrix substrate in which a decrease in transmittance caused by a contact hole formed in a flattened layer is suppressed.

The specification discloses an active matrix substrate and a liquid crystal display device described in the following items.

### Item 1

An active matrix substrate includes a display region defined by multiple pixel regions, a substrate, first TFTs supported by the substrate and disposed in the multiple pixel regions, respectively, a first flattened layer covering the first TFTs, and pixel electrodes provided on the first flattened layer and electrically connected to the first TFTs, respectively, each of the first TFTs including a lower gate electrode provided on the substrate, a lower gate insulating layer covering the lower gate electrode, an oxide semiconductor layer provided on the lower gate insulating layer, the oxide semiconductor layer including a channel region facing the lower gate electrode with the lower gate insulating layer interposed between the channel region and the lower gate electrode, and a source contact region located on one side of the channel region and a drain contact region located on another side of the channel region, an upper gate insulating layer provided on the channel region of the oxide semiconductor layer, and an upper gate electrode provided on the upper gate insulating layer and facing the channel region of the oxide semiconductor layer with the upper gate insulating layer interposed between the upper gate electrode and the channel region, in which the active matrix substrate includes first connection electrodes located under the first flattened layer, each of the first connection electrodes electrically connecting the drain contact region of the oxide semiconductor layer and each of the pixel electrodes, the first flattened layer includes pixel contact holes formed such that a portion of each of the first connection electrodes is exposed, as viewed from a normal direction of the substrate, a bottom face of each of the pixel contact holes overlaps, at least partially, at least a lower gate metal layer out of the lower gate metal layer including the lower gate electrode and an upper gate metal layer including the upper gate electrode, the first connection electrodes are formed from a transparent conductive material, the active matrix substrate further includes second connection electrodes formed from a transparent conductive material, each of the second connection electrodes electrically connecting each of the first connection electrodes and each of the pixel electrodes, and each of the second connection electrodes being in contact with each of the first connection electrodes in each of the pixel contact holes, and second flattened layers formed such that each of the pixel contact holes is filled with each of the second flattened layers, the second flattened layer covering a portion of each of the second connection electrodes, and a ratio of an equivalent circle diameter d2 of an upper face of each of the second flattened layers to an equivalent circle diameter d1 of a bottom face of each of the pixel contact holes is three or more and five or less.

### Item 2

The active matrix substrate according to item 1, in which in a cross section parallel to the normal direction of the substrate, in a case where an axis orthogonal to the normal direction of the substrate is defined as an x-axis, an axis parallel to the normal direction of the substrate is defined as a y-axis, and the lowest point of a side surface of each of the pixel contact holes is located on the x-axis in a range of x>0, the side surface of each of the pixel contact holes has a shape approximated by the following equation (1)

y=A*ln(x)+B (1)

where units of the x-axis and the y-axis are each μm, and 0.70≤A≤0.80, and B>0 are satisfied.

### Item 3

The active matrix substrate according to item 1 or 2, in which in a case where a region of an upper face of the first flattened layer in which the pixel contact holes are not formed is referred to as a flat region, a difference between a height of the highest portion of the upper face of each of the second flattened layers and a height of the flat region is 0.5 μm or less.

### Item 4

The active matrix substrate according to any one of items 1 to 3, in which each of the pixel electrodes is in contact with a portion of each of the second connection electrodes not covered with each of the second flattened layers, and each of the pixel electrodes includes a portion located on each of the second flattened layers.

### Item 5

The active matrix substrate according to any one of items 1 to 4, in which, as viewed from the normal direction of the substrate, the bottom face of each of the pixel contact holes overlaps, at least partially, at least the lower gate electrode out of the lower gate electrode and the upper gate electrode.

### Item 6

The active matrix substrate according to any one of items 1 to 4, in which the lower gate metal layer includes a lower gate wiring line electrically connected to the lower gate electrode, the upper gate metal layer includes an upper gate wiring line electrically connected to the upper gate electrode, and as viewed from the normal direction of the substrate, the bottom face of each of the pixel contact holes overlaps, at least partially, at least the lower gate wiring line out of the lower gate wiring line and the upper gate wiring line.

### Item 7

The active matrix substrate according to any one of items 1 to 4, in which, as viewed from the normal direction of the substrate, the bottom face of each of the pixel contact holes overlaps, at least partially, both the lower gate metal layer and the upper gate metal layer.

### Item 8

The active matrix substrate according to item 7, in which, as viewed from the normal direction of the substrate, the bottom face of each of the pixel contact holes overlaps, at least partially, both the lower gate electrode and the upper gate electrode.

### Item 9

The active matrix substrate according to item 7, in which the lower gate metal layer includes a lower gate wiring line electrically connected to the lower gate electrode, the upper gate metal layer includes an upper gate wiring line electrically connected to the upper gate electrode, and as viewed from the normal direction of the substrate, the bottom face of each of the pixel contact holes overlaps, at least partially, both the lower gate wiring line and the upper gate wiring line.

### Item 10

The active matrix substrate according to any one of items 1 to 4, in which, as viewed from the normal direction of the substrate, the bottom face of each of the pixel contact holes as a whole overlaps both the lower gate metal layer and the upper gate metal layer.

### Item 11

The active matrix substrate according to item 10, in which, as viewed from the normal direction of the substrate, the bottom face of each of the pixel contact holes as a whole overlaps both the lower gate electrode and the upper gate electrode.

### Item 12

The active matrix substrate according to item 10, in which the lower gate metal layer includes a lower gate wiring line electrically connected to the lower gate electrode, the upper gate metal layer includes an upper gate wiring line electrically connected to the upper gate electrode, and as viewed from the normal direction of the substrate, the bottom face of each of the pixel contact holes as a whole overlaps both the lower gate wiring line and the upper gate wiring line.

### Item 13

The active matrix substrate according to any one of items 1 to 12, in which each of the first TFTs includes a source electrode electrically connected to the source contact region, and as viewed from the normal direction of the substrate, the bottom face of each of the pixel contact holes overlaps, at least partially, a source metal layer including the source electrode.

### Item 14

The active matrix substrate according to item 13, in which the source metal layer includes an island-shaped electrode provided separated from the source electrode, and as viewed from the normal direction of the substrate, the bottom face of each of the pixel contact holes overlaps, at least partially, the island-shaped electrode.

### Item 15

The active matrix substrate according to item 13, in which the source metal layer includes a source wiring line electrically connected to the source electrode, and as viewed from the normal direction of the substrate, the bottom face of each of the pixel contact holes overlaps, at least partially, the source wiring line.

### Item 16

The active matrix substrate described in any one of items 1 to 15, in which a portion of each of the first connection electrodes is in contact with the drain contact region of the oxide semiconductor layer.

### Item 17

The active matrix substrate according to any one of items 1 to 16, in which the second connection electrodes and the pixel electrodes are formed from the same transparent conductive material.

### Item 18

The active matrix substrate according to item 17, in which the second connection electrodes and the pixel electrodes are formed from indium zinc oxide.

### Item 19

The active matrix substrate according to any one of items 1 to 18, in which the active matrix substrate includes a non-display region located around the display region, and the active matrix substrate further includes second TFTs provided in the non-display region and supported by the substrate, each of the second TFTs including a crystalline silicon semiconductor layer.

### Item 20

The active matrix substrate according to item 19, in which each of the second TFTs includes a gate electrode provided on an insulating layer covering the crystalline silicon semiconductor layer, the gate electrode facing the crystalline silicon semiconductor layer with the insulating layer interposed between the gate electrode and the crystalline silicon semiconductor layer, and the gate electrode of each of the second TFTs is formed in the same layer as the lower gate electrode of each of the first TFTs.

### Item 21

The active matrix substrate according to any one of items 1 to 20, in which the oxide semiconductor layer includes an In—Ga—Zn—O based semiconductor.

### Item 22

A liquid crystal display device including the active matrix substrate according to any one of items 1 to 21, a counter substrate provided facing the active matrix substrate, and a liquid crystal layer provided between the active matrix substrate and the counter substrate.

According to the embodiments of the disclosure, it is possible to provide an active matrix substrate capable of suppressing a decrease in transmittance caused by a contact hole formed in a flattened layer.

### BRIEF DESCRIPTION OF DRAWINGS

The disclosure will be described with reference to the accompanying drawings, wherein like numbers reference like elements.

FIG. 1 is a schematic view illustrating an example of a planar structure of an active matrix substrate 100 according to an embodiment of the disclosure.

FIG. 2 is a plan view schematically illustrating the active matrix substrate 100.

FIG. 3 is a cross-sectional view schematically illustrating the active matrix substrate 100, taken along line 3A-3A′ in FIG. 2.

FIG. 4 is a plan view schematically illustrating an active matrix substrate 900 in Comparative Example.

FIG. 5 is a cross-sectional view schematically illustrating the active matrix substrate 900, taken along line 5A-5A′ in FIG. 4.

FIG. 6 is a diagram for describing a reason why transmittance is reduced in the active matrix substrate 900.

FIG. 7 is a diagram for describing a reason why transmittance is improved in the active matrix substrate 100.

FIG. 8A is a diagram for describing a series of steps of filling a pixel contact hole CH_{P} with a second flattened layer 17.

FIG. 8B is a diagram for describing the series of steps of filling the pixel contact hole CH_{P} with the second flattened layer 17.

FIG. 8C is a diagram for describing the series of steps of filling the pixel contact hole CH_{P} with the second flattened layer 17.

FIG. 8D is a diagram for describing the series of steps of filling the pixel contact hole CH_{P} with the second flattened layer 17.

FIG. 8E is a diagram for describing the series of steps of filling the pixel contact hole CH_{P} with the second flattened layer 17.

FIG. 9 is a cross-sectional view illustrating the pixel contact hole CH_{P} and the vicinity of the pixel contact hole CH_{P} in the active matrix substrate 100.

FIG. 10 is a diagram illustrating a state in which, in a cross section parallel to a normal direction of a substrate 1, the lowest point p1 of a side surface 16s of the pixel contact hole CH_{P} is set as an origin, an axis that passes through the origin and is orthogonal to the normal direction of the substrate 1 is set as an x-axis, and an axis that passes through the origin and parallel to the normal direction of the substrate 1 is set as a y-axis.

FIG. 11A is a step cross-sectional view illustrating a manufacturing step for the active matrix substrate 100.

FIG. 11B is a step cross-sectional view illustrating a manufacturing step for the active matrix substrate 100.

FIG. 11C is a step cross-sectional view illustrating a manufacturing step for the active matrix substrate 100.

FIG. 11D is a step cross-sectional view illustrating a manufacturing step for the active matrix substrate 100.

FIG. 12A is a step cross-sectional view illustrating a manufacturing step for an active matrix substrate 100.

FIG. 12B is a step cross-sectional view illustrating a manufacturing step for the active matrix substrate 100.

FIG. 12C is a step cross-sectional view illustrating a manufacturing step for the active matrix substrate 100.

FIG. 13A is a step cross-sectional view illustrating a manufacturing step for the active matrix substrate 100.

FIG. 13B is a step cross-sectional view illustrating a manufacturing step for the active matrix substrate 100.

FIG. 13C is a step cross-sectional view illustrating a manufacturing step for the active matrix substrate 100.

FIG. 14A is a step cross-sectional view illustrating a manufacturing step for the active matrix substrate 100.

FIG. 14B is a step cross-sectional view illustrating a manufacturing step for the active matrix substrate 100.

FIG. 14C is a step cross-sectional view illustrating a manufacturing step for the active matrix substrate 100.

FIG. 15 is a diagram illustrating shapes of the second flattened layer 17 when a thermal history of post-baking during formation of the second flattened layer 17 is sufficiently increased, with an upper part illustrating a case of underexposure, a middle part illustrating a case of proper exposure, and a lower part illustrating a case of overexposure.

FIG. 16A is a scatter plot (graph) plotting a side shape of the pixel contact hole CH_{P} in Example, showing a case where no misalignment of a multi-tone photomask occurs.

FIG. 16B is a scatter plot (graph) plotting a side shape of the pixel contact hole CH_{P} in Example, showing a case where alignment of the multi-tone photomask is shifted in a negative direction (left in the figure).

FIG. 16C is a scatter plot (graph) plotting a side shape of the pixel contact hole CH_{P} in Example, showing a case where alignment of the multi-tone photomask is shifted in a positive direction (right in the figure).

FIG. 17A is a scatter plot (graph) plotting a side shape of the pixel contact hole CH_{P} in Reference Example 1, showing a case where no misalignment of the multi-tone photomask occurs.

FIG. 17B is a scatter plot (graph) plotting a side shape of the pixel contact hole CH_{P} in Reference Example 1, showing a case where alignment of the multi-tone photomask is shifted in the negative direction (left in the figure).

FIG. 17C is a scatter plot (graph) plotting a side shape of the pixel contact hole CH_{P} in Reference Example 1, showing a case where alignment of the multi-tone photomask is shifted in the positive direction (right in the figure).

FIG. 18A is a scatter plot (graph) plotting a side shape of the pixel contact hole CH_{P} in Reference Example 2, showing a case where no misalignment of the multi-tone photomask occurs.

FIG. 18B is a scatter plot (graph) plotting a side shape of the pixel contact hole CH_{P} in Reference Example 2, showing a case where alignment of the multi-tone photomask is shifted in the negative direction (left in the figure).

FIG. 18C is a scatter plot (graph) plotting a side shape of the pixel contact hole CH_{P} in Reference Example 2, showing a case where alignment of the multi-tone photomask is shifted in the positive direction (right in the figure).

FIG. 19 is a schematic view created based on a cross-sectional observation of the pixel contact hole CH_{P} in Reference Example 2.

FIG. 20 is a schematic view created based on a cross-sectional observation of the pixel contact hole CH_{P} in Example.

FIG. 21 is a cross-sectional view schematically illustrating a spacer receiving portion rp provided in the active matrix substrate 100.

FIG. 22 is a plan view schematically illustrating another active matrix substrate 200 according to an embodiment of the disclosure.

FIG. 23 is a cross-sectional view schematically illustrating the active matrix substrate 200, taken along line 23A-23A′ in FIG. 22.

FIG. 24 is a plan view schematically illustrating yet another active matrix substrate 300 according to an embodiment of the disclosure.

FIG. 25 is a cross-sectional view schematically illustrating the active matrix substrate 300, taken along line 25A-25A′ in FIG. 24.

FIG. 26 is a cross-sectional view schematically illustrating the active matrix substrate 300, taken along line 26A-26A′ in FIG. 24.

FIG. 27 is a cross-sectional view schematically illustrating still another active matrix substrate 400 according to an embodiment of the disclosure.

FIG. 28 is a cross-sectional view schematically illustrating a liquid crystal display device 1000 that includes the active matrix substrate 100, (200, 300, 400) according to an embodiment of the disclosure.

### DESCRIPTION OF EMBODIMENTS

Hereinafter, embodiments of the disclosure will be described with reference to the accompanying drawings. In the following, active matrix substrates for liquid crystal display devices will be exemplified as embodiments of the disclosure, but the disclosure is not limited to the following embodiments.

### First Embodiment

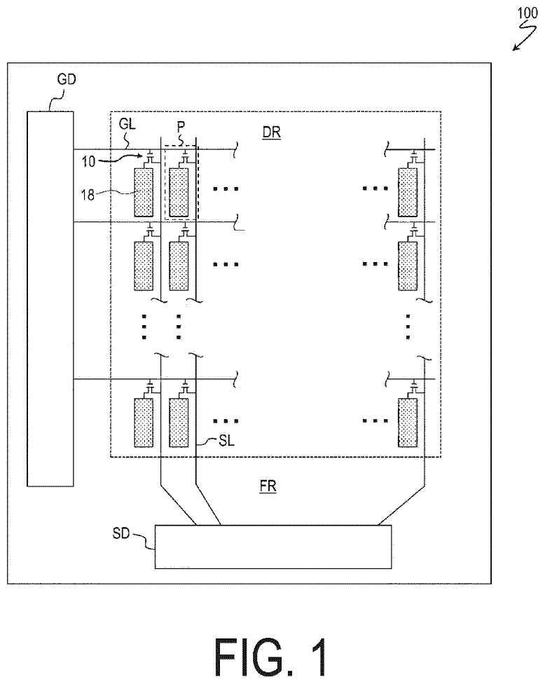

An active matrix substrate 100 according to the present embodiment will be described with reference to FIG. 1. FIG. 1 is a schematic view illustrating an example of a planar structure of the active matrix substrate 100.

The active matrix substrate 100 has a display region DR and a non-display region (also referred to as a “frame region”) FR as illustrated in FIG. 1. The display region DR is defined by a plurality of pixel regions P. The plurality of pixel regions P are arrayed in a matrix shape including a plurality of rows and a plurality of columns. The pixel region P is a region corresponding to a pixel of the liquid crystal display device, and the pixel region P may simply be called the “pixel”. The non-display region FR is a region located in a periphery of the display region DR and does not contribute to display.

In the display region DR, a plurality of gate wiring lines GL extending in a row direction, and a plurality of source wiring lines SL extending in a column direction are formed. Each pixel region P is, for example, a region surrounded by a pair of gate wiring lines GL adjacent to each other and a pair of source wiring lines SL adjacent to each other.

A peripheral circuit is provided in the non-display region FR. Here, in the non-display region FR, a gate driver GD for driving the gate wiring line GL is formed integrally (monolithically), and a source driver SD for driving a source wiring line SL is mounted. Note that in the non-display region FR, for example, a source shared driving (SSD) circuit that drives source bus lines SL in a time-division manner may be further disposed, and for example, the SSD circuit may be integrally formed like the gate driver GD.

In each pixel region P of the display region DR, a thin film transistor (TFT) 10 and a pixel electrode 18 electrically connected to the TFT 10 are disposed. The TFT 10 disposed in each pixel region P may be referred to as a “pixel TFT”. The TFT 10 is supplied with a gate signal (scanning signal) from a corresponding gate wiring line GL and supplied with a source signal (display signal) from a corresponding source wiring line SL. Note that for simplicity of description, FIG. 1 illustrates one gate wiring line GL for each pixel row, but as described below, a lower gate wiring line and an upper gate wiring line may be provided for each pixel row, and each TFT 10 may be supplied with gate signals from the lower gate wiring line and the upper gate wiring line.

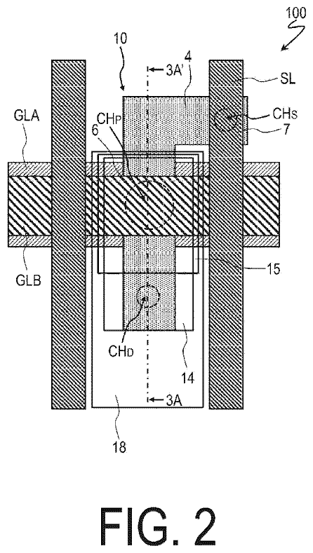

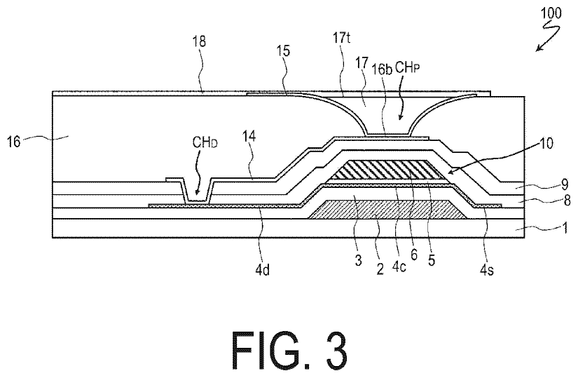

Next, a more specific configuration of the active matrix substrate 100 will be described with reference to FIGS. 2 and 3. FIG. 2 is a plan view schematically illustrating the active matrix substrate 100. FIG. 3 is a cross-sectional view schematically illustrating the active matrix substrate 100, taken along line 3A-3A′ in FIG. 2.

As illustrated in FIGS. 2 and 3, the active matrix substrate 100 includes a substrate 1, the TFTs 10 supported by the substrate 1, a flattened layer 16 covering the TFTs 10, and the pixel electrodes 18 provided on the flattened layer 16.

The substrate 1 is transparent and has insulating properties. The substrate 1 is, for example, a glass substrate or a plastic substrate.

The TFT 10 is disposed in each pixel region P. The TFT 10 includes a lower gate electrode 2, a lower gate insulating layer 3, an oxide semiconductor layer 4, an upper gate insulating layer 5, an upper gate electrode 6, and a source electrode 7. That is, the TFT 10 has a double gate structure.

The lower gate electrode 2 is provided on the substrate 1. The lower gate electrode 2 is electrically connected to a corresponding lower gate wiring line GLA. In the illustrated example, a portion of the lower gate wiring line GLA (to be specific, a portion facing the oxide semiconductor layer 4) functions as the lower gate electrode 2. In this specification, the lower gate electrode 2 and a wiring line and/or an electrode formed in the same layer as the lower gate electrode 2 (by patterning the same conductive film) are collectively referred to as a “lower gate metal layer”. Here, the lower gate metal layer includes the lower gate electrode 2 and the lower gate wiring line GLA. The lower gate insulating layer 3 covers the lower gate electrode 2.

The oxide semiconductor layer 4 is provided on the lower gate insulating layer 3. The oxide semiconductor layer 4 includes a channel region 4c facing the lower gate electrode 2 with the lower gate insulating layer 3 interposed therebetween, a source contact region 4s located on one side of the channel region 4c, and a drain contact region 4d located on another side.

The upper gate insulating layer 5 is provided on the channel region 4c of the oxide semiconductor layer 4. The upper gate electrode 6 is provided on the upper gate insulating layer 5 and faces the channel region 4c of the oxide semiconductor layer 4 with the upper gate insulating layer 5 interposed therebetween. The upper gate electrode 6 is electrically connected to a corresponding upper gate wiring line GLB. In the illustrated example, a portion of the upper gate wiring line GLB (to be specific, a portion facing the oxide semiconductor layer 4) functions as the upper gate electrode 6. In this specification, the upper gate electrode 6 and a wiring line and/or an electrode formed in the same layer as the upper gate electrode 6 (by patterning the same conductive film) are collectively referred to as an “upper gate metal layer”. Here, the upper gate metal layer includes the upper gate electrode 6 and the upper gate wiring line GLB. The upper gate electrode 6 may be given the same potential as the lower gate electrode 2, or may be given a different potential for threshold control. When the same potential is applied to the upper gate electrode 6 and the lower gate electrode 2, the upper gate wiring line GLB and the lower gate wiring line GLA may be electrically connected. When the same potential is applied to the upper gate electrode 6 and the lower gate electrode 2, one of the upper gate electrode 6 and the lower gate electrode 2 may be an island-shaped electrode electrically connected to the other.

A first interlayer insulating layer 8 is provided so as to cover the upper gate electrode 6 and the oxide semiconductor layer 4. The source electrode 7 is provided on the first interlayer insulating layer 8. In the first interlayer insulating layer 8, a source contact hole CH_{S} is formed so that a portion of the source contact region 4s of the oxide semiconductor layer 4 is exposed. The source electrode 7 is in contact with the source contact region 4s in the source contact hole, and is electrically connected to the source contact region 4s. The source electrode 7 is electrically connected to a corresponding source wiring line SL. In the illustrated example, a portion of the source wiring line SL (to be specific, a portion facing the oxide semiconductor layer 4) functions as the source electrode 7. In this specification, the source electrode 7 and a wiring line and/or an electrode formed in the same layer as the source electrode 7 (by patterning the same conductive film) are collectively referred to as a “source metal layer”. Here, the source metal layer includes the source electrode 7 and the source wiring line SL.

A second interlayer insulating layer 9 is provided so as to cover the TFT 10, and the flattened layer 16 is formed on the second interlayer insulating layer 9. The flattened layer 16 is formed, for example, from a photosensitive resin material. The pixel electrode 18 is provided on the flattened layer 16. The pixel electrode 18 is electrically connected to the TFT 10.

The exemplified active matrix substrate 100 is used in a fringe field switching (FFS) mode liquid crystal display device, and further includes a dielectric layer provided so as to cover the pixel electrodes 18, and a common electrode provided on the dielectric layer and facing the pixel electrodes 18, although these are not illustrated here. At least one slit is formed in the common electrode for each pixel region P.

The active matrix substrate 100 includes a connection electrode 14 located under the flattened layer 16 for electrically connecting the drain contact region 4d of the oxide semiconductor layer 4 and the pixel electrode 18. The connection electrode 14 is formed from a transparent conductive material and is provided on the second interlayer insulating layer 9. In the first interlayer insulating layer 8 and the second interlayer insulating layer 9, a drain contact hole CH_{D} is formed so that a portion of the drain contact region 4d of the oxide semiconductor layer 4 is exposed. A portion of the connection electrode 14 is in contact with the drain contact region 4d in the drain contact hole CH_{D}.

The flattened layer 16 has a pixel contact hole CH_{P} formed so that a portion of the connection electrode 14 is exposed. A portion of the pixel electrode 18 is in contact with the connection electrode 14 in the pixel contact hole CH_{P}. Here, an upper face and a bottom face 16b of the pixel contact hole CH_{P} are both substantially circular.

When viewed from the normal direction of the substrate 1, the bottom face 16b of the pixel contact hole CH_{P} overlaps, at least partially, both the lower gate metal layer and the upper gate metal layer. To be more specific, the bottom face 16b of the pixel contact hole CH_{P} overlaps, at least partially, both the lower gate electrode 2 and the upper gate electrode 6. In the illustrated example, the bottom face 16b of the pixel contact hole CH_{P} as a whole overlaps both the lower gate metal layer and the upper gate metal layer, to be more specific, both the lower gate electrode 2 and the upper gate electrode 6.

As illustrated in FIG. 3, the active matrix substrate 100 according to the present embodiment includes a further connection electrode 15 and a further flattened layer 17 in addition to the connection electrode 14 and the flattened layer 16 already described. In the following description, the connection electrode 14 and the flattened layer 16 are referred to as a “first connection electrode” and a “first flattened layer”, respectively, and the further connection electrode 15 and the further flattened layer 17 are referred to as a “second connection electrode” and a “second flattened layer”, respectively.

The second connection electrode 15 is formed from a transparent conductive material, and electrically connects the first connection electrode 14 and the pixel electrode 18. The second connection electrode 15 is in contact with the first connection electrode 14 in the pixel contact hole CH_{P}.

The second flattened layer 17 is formed so that the pixel contact hole CH_{P} is filled with the second flattened layer 17. The second flattened layer 17 covers a portion of the second connection electrode 15. The second flattened layer 17 is formed from, for example, a photosensitive resin material. Here, an upper face 17t and a bottom face of the second flattened layer 17 are both substantially circular.

The pixel electrode 18 is in contact with a portion of the second connection electrode 15 that is not covered with the second flattened layer 17. The pixel electrode 18 includes a portion located on the second flattened layer 17.

Here, the second connection electrode 15 and the pixel electrode 18 are formed from the same transparent conductive material. The second connection electrode 15 and the pixel electrode 18 are formed from, for example, indium tin oxide (ITO) or indium zinc oxide (IZO).

As described above, in the active matrix substrate 100 according to the present embodiment, the bottom face 16b of the pixel contact hole CH_{P} formed in the first flattened layer 16 overlaps, at least partially, both the lower gate electrode 2 and the upper gate electrode 6. In addition, the first connection electrode 14 for electrically connecting the drain contact region 4d of the oxide semiconductor layer 4 and the pixel electrode 18 is formed from a transparent conductive material. The active matrix substrate 100 having such a configuration can improve transmittance. The reasons for this will be described below.

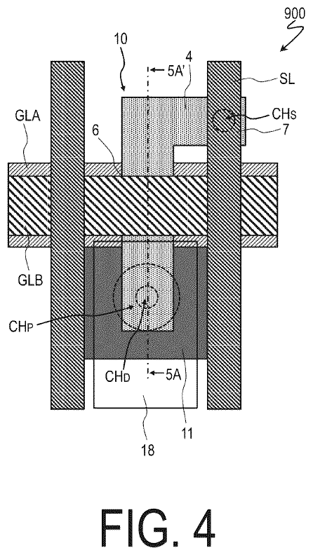

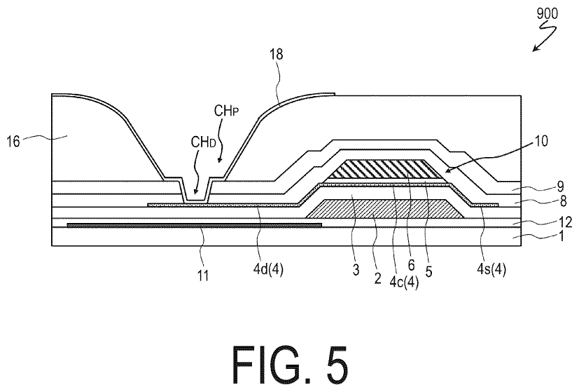

FIGS. 4 and 5 illustrate an active matrix substrate 900 in Comparative Example. FIG. 4 is a plan view schematically illustrating the active matrix substrate 900. FIG. 5 is a cross-sectional view schematically illustrating the active matrix substrate 900, taken along line 5A-5A′ in FIG. 4.

The active matrix substrate 900 in Comparative Example includes the TFT 10 having a double gate structure, similar to the active matrix substrate 100. However, in the active matrix substrate 900 in Comparative Example, when viewed from the normal direction of the substrate 1, the pixel contact hole CH_{P} formed in the flattened layer 16 overlaps neither the lower gate electrode 2 nor the upper gate electrode 6 but overlaps the drain contact region 4d of the oxide semiconductor layer 4. The pixel contact hole CH_{P} is disposed such that, when viewed from the normal direction of the substrate 1, the drain contact hole CH_{D} formed in the first interlayer insulating layer 8 and the second interlayer insulating layer 9 is located in the pixel contact hole CH_{P}. A portion of the pixel electrode 18 is in contact with the drain contact region 4d of the oxide semiconductor layer 4 in the drain contact hole CH_{D}, and thus the pixel electrode 18 is electrically connected to the oxide semiconductor layer 4. Therefore, the active matrix substrate 900 in Comparative Example does not include the first connection electrode 14 or the second connection electrode 15.

The active matrix substrate 900 in Comparative Example includes a light blocking layer 11 disposed so as to overlap the pixel contact hole CH_{P} when viewed from the normal direction of the substrate 1. The light blocking layer 11 is formed on the substrate 1, and a base coat layer 12 is provided so as to cover the light blocking layer 11. The TFT 10 is formed on the base coat layer 12.

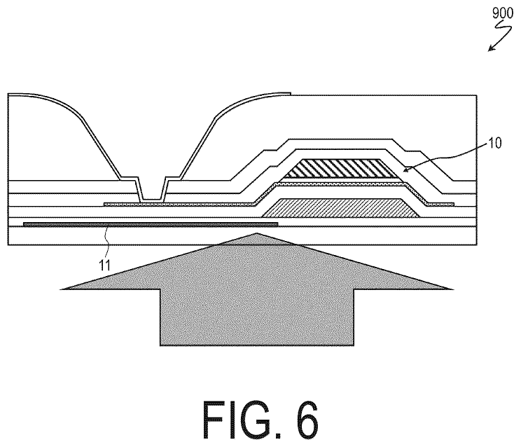

In the active matrix substrate 900 in Comparative Example, in order to reliably electrically connect the pixel electrode 18 and the oxide semiconductor layer 4, the drain contact hole CH_{D} and the pixel contact hole CH_{P} need to be formed so as to overlap each other. However, when positions of the drain contact hole CH_{D} and the pixel contact hole CH_{P} are too close, the photosensitive resin material constituting the flattened layer 16 may remain at a bottom of the drain contact hole CH_{D}, which may result in poor conductivity. Therefore, an opening diameter of the pixel contact hole CH_{P} needs to be sufficiently large relative to an opening diameter of the drain contact hole CH_{D}, and thus an exposure time when forming the pixel contact hole CH_{P} needs to be set to be sufficiently long. Accordingly, the pixel contact hole CH_{P} has a gentle cone shape having a tapered side surface that spreads from the bottom face of the pixel contact hole CH_{P}. Thus, it is difficult to reduce the opening diameter of the pixel contact hole CH_{P} relative to the opening diameter of the drain contact hole CH_{D}. The pixel contact hole CH_{P} having such a shape disturbs alignment of liquid crystal molecules, which causes decreases in a contrast ratio and display quality due to light leakage in the liquid crystal display device. Therefore, it is necessary to block light from reaching the vicinity of the pixel contact hole CH_{P} by the light blocking layer 11 of the active matrix substrate 900 and a black matrix provided on a counter substrate. However, in that case, as illustrated in FIG. 6, light from a backlight is blocked by the light blocking layer 11 and the black matrix, resulting in a decrease in transmittance.

As already described, JP 2017-187714 A discloses a configuration that can make a contact hole formed in a flattened layer (organic insulating film) shallower. In the configuration disclosed in JP 2017-187714 A, an electrode (metal portion) that electrically connects a polysilicon semiconductor layer, which is an active layer of a TFT, and a pixel electrode is raised by a pedestal portion provided directly under the electrode, whereby a contact hole formed in a flattened layer can be made shallower.

However, when a complicated structure such as that disclosed in JP 2017-187714 A is actually formed in a pixel, light leakage is a concern. For example, a phenomenon in which an edge of the metal portion formed in an island shape shines (striation phenomenon) may occur. In order to prevent light leakage due to such a striation phenomenon, it is considered necessary to block the light from reaching the vicinity of the metal portion (the vicinity of the pedestal portion) by the light blocking layer of the active matrix substrate and the black matrix of the counter substrate. Therefore, when the configuration disclosed in JP 2017-187714 A is employed, although the contact hole can be formed to be shallow, it is difficult to significantly improve transmittance (significantly improve aperture ratio).

In contrast, in the active matrix substrate 100 according to the present embodiment, when viewed from the normal direction of the substrate 1, the bottom face 16b of the pixel contact hole CH_{P} overlaps, at least partially, both the lower gate electrode 2 and the upper gate electrode 6. Thus, when the photosensitive resin material is exposed, a thickness of the photosensitive resin material in the region where the pixel contact hole CH_{P} is formed is reduced by thicknesses of the lower gate electrode 2 and the upper gate electrode 6, and the exposure light is reflected by the lower gate electrode 2 and/or the upper gate electrode 6, so that the pixel contact hole CH_{P} can be formed with a shorter exposure time and a smaller mask pattern. Therefore, the opening diameter of the pixel contact hole CH_{P} can be reduced. Since the opening diameter of the pixel contact hole CH_{P} can be reduced, the lower gate electrode 2 and the upper gate electrode 6 can sufficiently block light without forming a light blocking layer, thereby improving transmittance. In the active matrix substrate 100 according to the present embodiment, it is not necessary to separately form a structure such as the pedestal portion disclosed in JP 2017-187714 A.

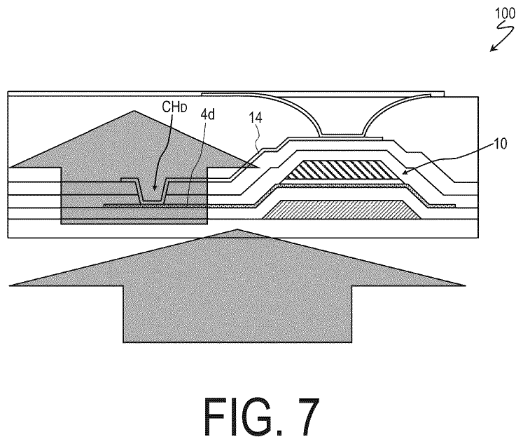

In the active matrix substrate 100 according to the present embodiment, the first connection electrode 14 for electrically connecting the drain contact region 4d of the oxide semiconductor layer 4 and the pixel electrode 18 is formed from a transparent conductive material. Therefore, as illustrated in FIG. 7, a periphery of the drain contact region 4d (periphery of the drain contact hole CH_{D}) can be made to contribute to display, and the aperture ratio can be increased to further improve transmittance.

Note that, when a polysilicon semiconductor layer is used as an active layer of a TFT as disclosed in JP 2017-187714 A, a junction between a material exhibiting n-type semiconductor characteristics, such as ITO or IZO, used as a transparent conductive material and the polysilicon semiconductor is a heterojunction between different semiconductors having significantly different energy levels, and is not an ohmic contact, so that a direct contact is not possible. Therefore, the material for forming the connection electrode for electrically connecting the polysilicon semiconductor layer and the pixel electrode is limited to a metal material. In contrast, when the active layer of the TFT 10 is the oxide semiconductor layer 4 as in the present embodiment, components and electrical characteristics are similar to those of a transparent conductive material (e.g., ITO or IZO), so the first connection electrode 14 can be formed from a transparent conductive material. When the first connection electrode 14 is formed from a transparent conductive material, the striation phenomenon does not occur, and the periphery of the drain contact hole CH_{D} can contribute to display.

Note that, when viewed from the normal direction of the substrate 1, in a case where the bottom face 16b of the pixel contact hole CH_{P} overlaps, at least partially, at least the lower gate electrode 2 out of the lower gate electrode 2 and the upper gate electrode 6, the opening diameter of the pixel contact hole CH_{P} can be reduced, thereby obtaining an effect of improving transmittance. However, from the viewpoint of further improving transmittance, it is preferable that the bottom face 16b of the pixel contact hole CH_{P} overlap, at least partially, both the lower gate electrode 2 and the upper gate electrode 6, and it is more preferable that the bottom face 16b of the pixel contact hole CH_{P} as a whole overlap both the lower gate electrode 2 and the upper gate electrode 6.

As described above, in the active matrix substrate 100 according to the present embodiment, a decrease in transmittance caused by the pixel contact hole CH_{P} is suppressed.

In the active matrix substrate 100 according to the present embodiment, the second flattened layer 17 is formed so that the pixel contact hole CH_{P} is filled with the second flattened layer 17, which suppresses alignment disorder of liquid crystal molecules caused by the pixel contact hole CH_{P}, thereby enabling a further improvement in transmittance. Note that FIG. 3 illustrates an example in which a size of the second connection electrode 15 is smaller than a size of the pixel electrode 18, but the size of the second connection electrode 15 may be substantially the same as the size of the pixel electrode 18.

The second flattened layer 17 can be formed, for example, by coating, exposing, developing, and baking (post-baking) a photosensitive resin material. By using a multi-tone photomask as a photomask during exposure, the pixel contact hole CH_{P} can be filled with the second flattened layer 17 with high accuracy. To be specific, a gray tone mask or a half tone mask can be used as the multi-tone photomask. Slits that are smaller than or equal to resolution of an exposure system are formed in the gray tone mask, and intermediate exposure is achieved by blocking part of light by these slits. On the other hand, intermediate exposure is achieved by using a transflective film in the half tone mask.

As described above, by adopting the configuration in which the pixel contact hole CH_{P} is filled with the second flattened layer 17, the alignment disorder caused by the pixel contact hole CH_{P} can be suppressed. However, according to study of the inventors, it has been found that in the configuration in which the pixel contact hole CH_{P} is filled with the second flattened layer 17, a new problem may arise as described below.

In a manufacturing process of active matrix substrates for display devices, techniques such as chemical mechanical polishing (CMP) are not commonly used as flattening techniques. Therefore, it is important to flatten the pixel contact hole CH_{P} with high accuracy by a photolithography process.

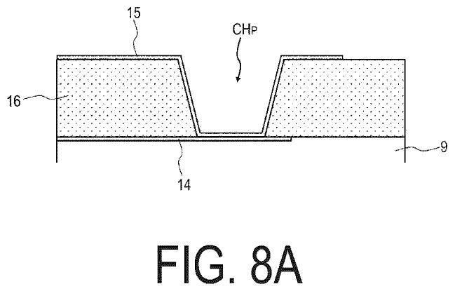

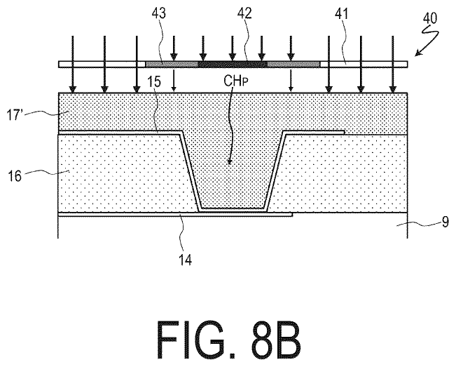

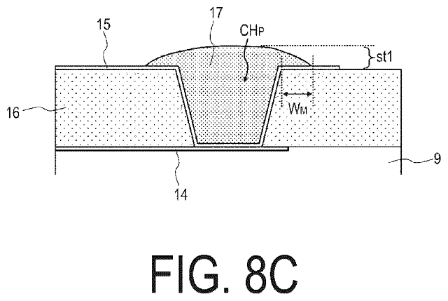

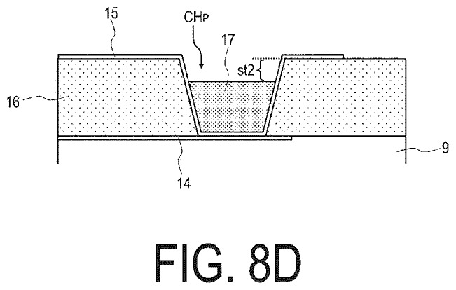

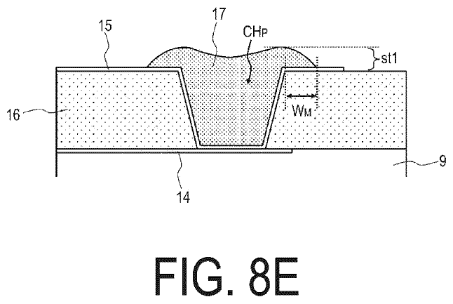

However, in reality, it is necessary to provide a design margin to accommodate deviations due to alignment variations during photolithography and variations in finished width. FIGS. 8A, 8B, and 8C are diagrams for describing a series of steps of filling the pixel contact hole CH_{P} with the second flattened layer 17.

FIG. 8A illustrates a state in which the second connection electrode 15 is formed on the first flattened layer 16 having the pixel contact hole CH_{P}. In this state, as illustrated in FIG. 8B, a photosensitive resin material 17′ (here, a positive type) is applied onto the first flattened layer 16 and the second connection electrode 15, and then exposure is performed using a multi-tone photomask 40. The multi-tone photomask 40 has a transmissive region 41 that transmits light, a light blocking region 42 that substantially does not transmit light, and a transflective region 43 that transmits light with a lower transmittance than the transmissive region 41. When the multi-tone photomask 40 is a half tone mask, a transflective film is used for the transflective region 43. When the multi-tone photomask 40 is a gray tone mask, slits equal to or smaller than the resolution of an exposure system are formed in the transflective region 43. Hereinafter, the light blocking region 42 and the transflective region 43 may be collectively referred to as a “light adjustment region”. In addition, the transflective region 43 may be divided into multiple regions, and the transmittances of these regions may be adjusted as desired. In that case, the multi-tone photomask 40 does not need to include the light blocking region 42.

Thereafter, by performing development and post-baking, a structure in which the pixel contact hole CH_{P} is filled with the second flattened layer 17 is obtained as illustrated in FIG. 8C. However, as already described, since a design margin is provided, the second flattened layer 17 not only fills the pixel contact hole CH_{P} but also covers the vicinity of the periphery of the pixel contact hole CH_{P} with a width Wy corresponding to the design margin. Therefore, a step st1 is formed in the vicinity of the periphery of the pixel contact hole CH_{P}. It is conceivable to increase an amount of exposure in order to avoid the formation of the step st1, but in that case, as illustrated in FIG. 8D, the second flattened layer 17 is reduced more than necessary, resulting in the formation of a step st2 in the pixel contact hole CH_{P}. Note that the shape of the second flattened layer 17 is not limited to the shape exemplified in FIG. 8C. The shape of the second flattened layer 17 can be appropriately controlled by changing the arrangement of the light blocking region 42 and the transflective region 43 in the multi-tone photomask 40. For example, when the light blocking region 42 and the transflective region 43 in the multi-tone photomask 40 illustrated in FIG. 8B are interchanged, the second flattened layer 17 having a slightly recessed shape at the center is obtained as illustrated in FIG. 8E.

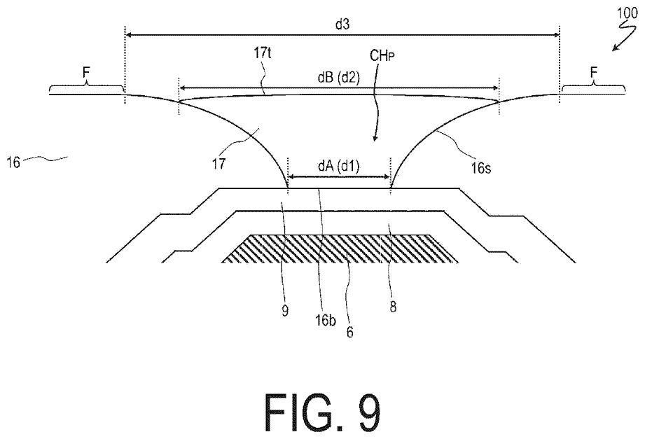

As a result of intensive studies on the structure of the pixel contact hole CH_{P}, the inventors have found a structure suitable for suppressing the formation of steps. Hereinafter, a preferable structure of the pixel contact hole CH_{P} will be described with reference to FIG. 9.

A ratio of a diameter dB of the upper face 17t of the second flattened layer 17 to a diameter dA of the bottom face 16b of the pixel contact hole CH_{P} is preferably three or more and five or less. That is, the diameter dB is preferably three times or more and five times or less the diameter dA. The diameter dB being three times or more and five times or less the diameter dA means that a side surface 16s of the pixel contact hole CH_{P} has a relatively gentle tapered shape. When the diameter dB is three times or more and five times or less the diameter dA, as will be described later in detail, even when exposure variations occur during the formation of the second flattened layer 17, such variations are mainly reflected as lateral size variations of the second flattened layer 17, so that vertical size variations of the second flattened layer 17 can be suppressed.

Note that the shapes of the bottom face 16b of the pixel contact hole CH_{P} and the upper face 17t of the second flattened layer 17 are not limited to a substantially circular shape, but may be any of various shapes such as a substantially elliptical shape, a substantially rectangular shape, and a substantially regular polygonal shape. Since the sizes of the bottom face 16b of the pixel contact hole CH_{P} and the upper face 17t of the second flattened layer 17 can be represented by equivalent circle diameters, the above-described preferable structure can be generalized as “a structure in which a ratio of an equivalent circle diameter d2 of the upper face 17t of the second flattened layer 17 to an equivalent circle diameter d1 of the bottom face 16b of the pixel contact hole CH_{P} is three or more and five or less”.

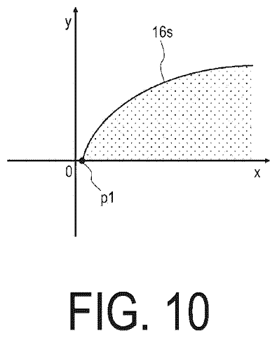

It is preferable that the side surface 16s of the pixel contact hole CH_{P} have a logarithmic curvature. To be specific, as illustrated in FIG. 10, in a cross section parallel to the normal direction of the substrate 1, an axis orthogonal to the normal direction of the substrate 1 is defined as an x-axis, an axis parallel to the normal direction of the substrate 1 is defined as a y-axis, and the lowest point p1 of the side surface 16s of the pixel contact hole CH_{P} is located on the x-axis in a range of x>0, then the side surface 16s of the pixel contact hole CH_{P} has a shape approximated by the following equation (1) (e.g., approximated by curve fitting using regression analysis).

y=A*ln(x)+B (1)

Here, units of the x-axis and the y-axis are both μm. In the equation (1), A is a value within a range of 0.75±0.05 (i.e., 0.70≤A≤0.80). B is any constant greater than 0 (i.e., B>0).

When a region F of an upper face of the first flattened layer 16 in which the pixel contact hole CH_{P} is not formed (see FIG. 9) is referred to as a “flat region”, the highest portion of the upper face of the second flattened layer 17 may be substantially the same height as the flat region F, or may be slightly higher than the flat region F, or may be slightly lower than the flat region F. However, a difference between a height h1 of the highest portion of the upper face of the second flattened layer 17 and a height h2 of the flat region F is preferably 0.5 μm or less. As long as the height h1 and the height h2 satisfy this relationship, an equivalent circle diameter d3 of the upper face of the pixel contact hole CH_{P} may be substantially the same as the equivalent circle diameter d2 of the upper face 17t of the second flattened layer 17, or may be larger or smaller than the equivalent circle diameter d2 of the upper face 17t of the second flattened layer 17.

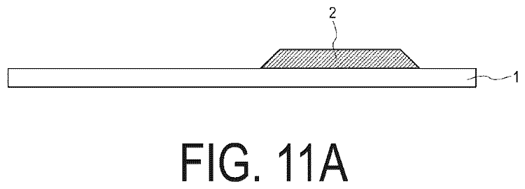

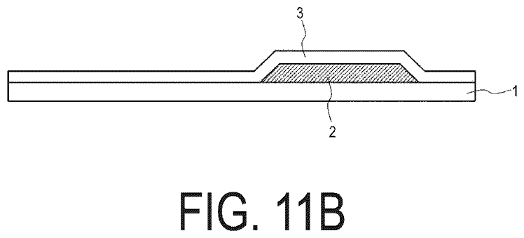

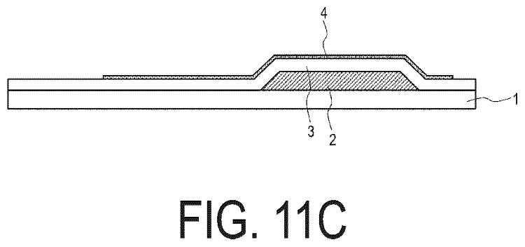

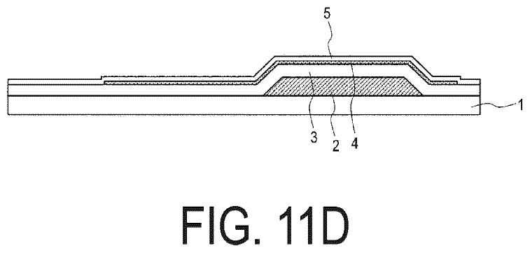

An example of a method of manufacturing the active matrix substrate 100 according to the present embodiment will be described with reference to FIGS. 11A to 14C. FIGS. 11A to 14C are step cross-sectional views illustrating manufacturing steps for the active matrix substrate 100.

First, as illustrated in FIG. 11A, the lower gate electrode 2 and the lower gate wiring line GLA (i.e., the lower gate metal layer) are formed on the substrate 1. For example, a conductive film is deposited by sputtering, and then the conductive film is patterned by a photolithography process, thereby forming the lower gate electrode 2 and the lower gate wiring line GLA.

For example, a glass substrate, a silicon substrate, a plastic substrate (resin substrate) having heat resistance, or the like can be used as the substrate 1. As the conductive film for forming the lower gate electrode 2 and the lower gate wiring line GLA (lower gate metal film), a film containing a metal such as aluminum (Al), tungsten (W), molybdenum (Mo), tantalum (Ta), chromium (Cr), titanium (Ti), or copper (Cu), or an alloy thereof, or a metal nitride thereof, can be appropriately used. A layered film obtained by layering these plurality of films may also be used. Here, a film in which a tantalum nitride (TaN) film and a W film are layered in this order is used as the lower gate metal film. A thickness of the lower gate metal film is, for example, 100 nm or more and 500 nm or less.

Subsequently, as illustrated in FIG. 11B, the lower gate insulating layer 3 is formed so as to cover the lower gate electrode 2 and the lower gate wiring line GLA. For example, the lower gate insulating layer 3 can be formed by CVD. As the lower gate insulating layer 3, a silicon oxide (SiO₂) layer, a silicon nitride (SiNx) layer, a silicon oxynitride (SiOxNy; x>y) layer, a silicon nitride oxide (SiNxOy; x>y) layer, or the like can be used as appropriate. The lower gate insulating layer 3 may have a layered structure. For example, a SiNx layer may be formed on the substrate 1 side as a lower layer in order to prevent diffusion of impurities and the like from the substrate 1, and a SiO₂ layer may be formed on top of the SiNx layer as an upper layer in order to ensure insulating properties. A thickness of the lower gate insulating layer 3 is 150 nm or more and 400 nm or less.

Subsequently, as illustrated in FIG. 11C, the oxide semiconductor layer 4 is formed on the lower gate insulating layer 3. For example, an oxide semiconductor film is deposited by sputtering, and then the oxide semiconductor film is patterned by a photolithography process, thereby forming the island-shaped oxide semiconductor layer 4. The oxide semiconductor layer 4 is formed so as to face the lower gate electrode 2 with the lower gate insulating layer 3 interposed therebetween. Here, as the oxide semiconductor layer 4, an In—Ga—Zn—O based semiconductor layer having a composition ratio of In:Ga:Zn=1:1:1 is formed. A thickness of the oxide semiconductor layer 4 is, for example, 10 nm or more and 200 nm or less.

Subsequently, as illustrated in FIG. 11D, the upper gate insulating layer 5 is deposited so as to cover the oxide semiconductor layer 4. The upper gate insulating layer 5 is deposited, for example, by CVD. Thereafter, the oxide semiconductor layer 4 is subjected to an oxidation treatment (e.g., baking or peroxide treatment). As the upper gate insulating layer 5, for example, an insulating layer similar to the lower gate insulating layer 3 (exemplified as the lower gate insulating layer 3) can be used. Here, as the upper gate insulating layer 5, a silicon oxide (SiO₂) layer is formed. when an oxide layer such as a silicon oxide layer is used as the upper gate insulating layer 5, oxygen deficiencies generated in the channel region 4c of the oxide semiconductor layer 4 can be reduced by the oxide layer, so that a decrease in resistance of the channel region can be suppressed. A thickness of the upper gate insulating layer 5 is, for example, 50 nm or more and 150 nm or less.

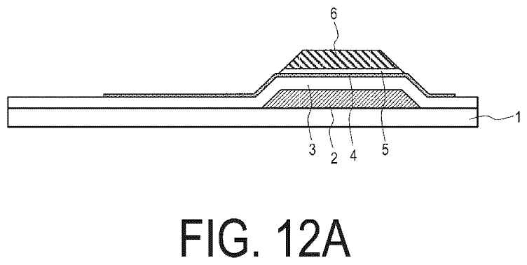

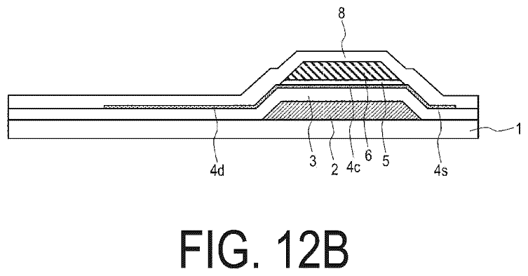

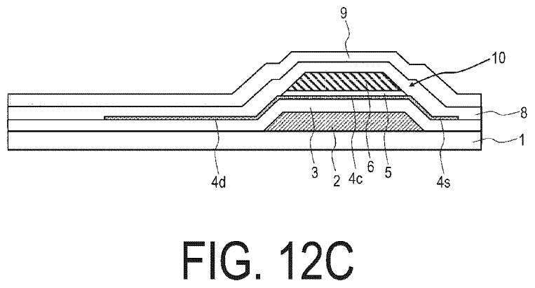

Subsequently, as illustrated in FIG. 12A, the upper gate electrode 6 and the upper gate wiring line GLB (i.e., the upper gate metal layer) are formed on the upper gate insulating layer 5. For example, a conductive film (upper gate metal film) is deposited by sputtering, and then the upper gate metal film is patterned by a photolithography process, thereby forming the upper gate electrode 6 and the upper gate wiring line GLB. Thereafter, the upper gate insulating layer 5 is patterned. Note that the upper gate insulating layer 5 may be patterned together with the upper gate metal film. As the upper gate metal film, for example, a film containing a metal such as aluminum (Al), tungsten (W), molybdenum (Mo), tantalum (Ta), chromium (Cr), titanium (Ti), or copper (Cu), or an alloy thereof, or a metal nitride thereof, can be used. Here, a film in which a Ti film, an Al film, and a Ti film are layered in this order is used as the upper gate metal film. A thickness of the upper gate metal film is, for example, 100 nm or more and 400 nm or less.

Thereafter, a treatment for reducing resistance of the oxide semiconductor layer 4 may be performed using the upper gate insulating layer 5 and the upper gate electrode 6 as masks. As the treatment for reducing resistance, a plasma treatment, for example, may be used. As a result of the treatment for reducing resistance, regions of the oxide semiconductor layer 4 that do not overlap the upper gate insulating layer 5 or the upper gate electrode 6 (regions that become the source contact region 4s and the drain contact region 4d) are low-resistive regions having a lower specific resistance than a region of the oxide semiconductor layer 4 that overlaps the upper gate insulating layer 5 and the upper gate electrode 6 (a region that becomes the channel region 4c). The low-resistive region may be a conductive region (for example, sheet resistance equal to or less than 200Ω/□). Note that the plasma treatment may be performed using the upper gate electrode 6 as a mask without patterning the upper gate insulating layer 5. In that case, the photolithography process for the upper gate insulating layer 5 can be omitted, so that the manufacturing process can be shortened. A treatment method for reducing resistance is not limited to the plasma treatment. For example, it is also possible to reduce resistance by bringing an exposed region of the oxide semiconductor layer 4 into contact with a reductive insulating film capable of reducing an oxide semiconductor. Alternatively, the resistance can be reduced by subjecting the oxide semiconductor layer 4 to an ion implantation process such as ion doping. Also in this case, the ion implantation process can be performed through the upper gate insulating layer 5, and thus the process can be shortened.

Subsequently, as illustrated in FIG. 12B, the first interlayer insulating layer 8 is formed to cover the oxide semiconductor layer 4 and the upper gate electrode 6. For example, the first interlayer insulating layer 8 can be formed by CVD. As the first interlayer insulating layer 8, an inorganic insulating layer such as a silicon oxide (SiO₂) layer, a silicon nitride (SiNx) layer, a silicon oxynitride (SiOxNy; x>y) layer, or a silicon nitride oxide (SiNxOy; x>y) layer can be used in a single layer or in layers. A thickness of the first interlayer insulating layer 8 is, for example, 200 nm or more and 700 nm or less. Here, a silicon oxide layer is used as the first interlayer insulating layer 8.

Subsequently, the source contact hole CH_{S} is formed in the first interlayer insulating layer 8 so that a portion of the source contact region 4s of the oxide semiconductor layer 4 is exposed. The source contact hole CH_{S} can be formed, for example, by patterning the first interlayer insulating layer 8 by a photolithography process.

Subsequently, the source electrode 7 and the source wiring line SL (i.e., the source metal layer) are formed on the first interlayer insulating layer 8. For example, a conductive film is deposited by sputtering, and then the conductive film is patterned by a photolithography process, thereby forming the source electrode 7 and the source wiring line SL. As the conductive film for forming the source electrode 7 and the source wiring line SL (source metal film), a film containing a metal such as aluminum (Al), tungsten (W), molybdenum (Mo), tantalum (Ta), copper (Cu), chromium (Cr), or titanium (Ti), or an alloy thereof, or a metal nitride thereof, can be appropriately used. A layered film obtained by layering these plurality of films may also be used. Here, a film in which a Ti film, an Al film, and a Ti film are layered in this order is used as the source metal film. A thickness of the source metal film is, for example, 200 nm or more and 700 nm or less.

Subsequently, as illustrated in FIG. 12C, the second interlayer insulating layer 9 is formed to cover the TFT 10. For example, the second interlayer insulating layer 9 can be formed by CVD. As the second interlayer insulating layer 9, an inorganic insulating layer such as a silicon oxide (SiO₂) layer, a silicon nitride (SiNx) layer, a silicon oxynitride (SiOxNy; x>y) layer, or a silicon nitride oxide (SiNxOy; x>y) layer can be used in a single layer or in layers. A thickness of the second interlayer insulating layer 9 is, for example, 100 nm or more and 600 nm or less. Here, a silicon nitride layer is used as the second interlayer insulating layer 9.

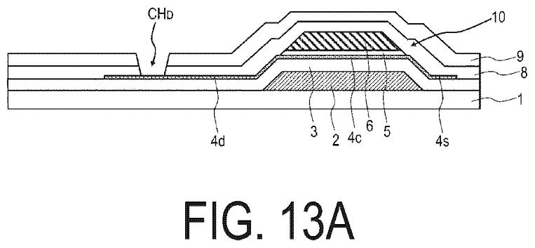

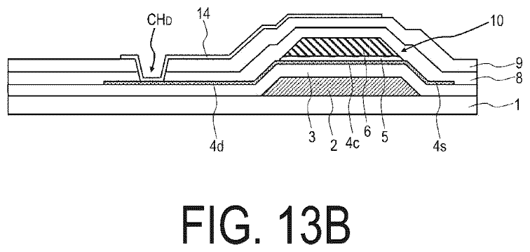

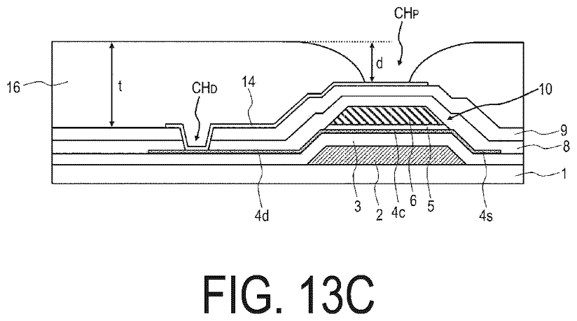

Subsequently, as illustrated in FIG. 13A, the drain contact hole CH_{D} is formed in the first interlayer insulating layer 8 and the second interlayer insulating layer 9 so that a portion of the drain contact region 4d of the oxide semiconductor layer 4 is exposed. The drain contact hole CH_{D} can be formed, for example, by patterning the first interlayer insulating layer 8 and the second interlayer insulating layer 9 by a photolithography process.

Subsequently, as illustrated in FIG. 13B, the first connection electrode 14 is formed on the second interlayer insulating layer 9. For example, a transparent conductive film is deposited by sputtering, and then the transparent conductive film is patterned by a photolithography process, thereby forming the first connection electrode 14. As a transparent conductive material for forming the first connection electrode 14, for example, indium tin oxide (ITO) or indium zinc oxide (IZO) can be used. Here, indium zinc oxide is used. A thickness of the first connection electrode 14 is, for example, 30 nm or more and 100 nm or less.

Subsequently, as illustrated in FIG. 13C, the first flattened layer 16 is formed to cover the second interlayer insulating layer 9 and the first connection electrode 14. For example, by applying a photosensitive resin material and sequentially performing exposure, development, and post-baking, the first flattened layer 16 in which the pixel contact hole CH_{P} is formed so that a portion of the first connection electrode 14 is exposed is obtained. As the photosensitive resin material, for example, a photosensitive acrylic resin can be used. A thickness t of the first flattened layer 16 in a flat portion (a portion not overlapping the lower gate electrode 2 and the upper gate electrode 6) is, for example, about 2.5 μm to 3.0 μm. When a thickness of each of the lower gate electrode 2 and the upper gate electrode 6 is about 300 nm, a depth d of the pixel contact hole CH_{P} is, for example, about 2.2 μm.

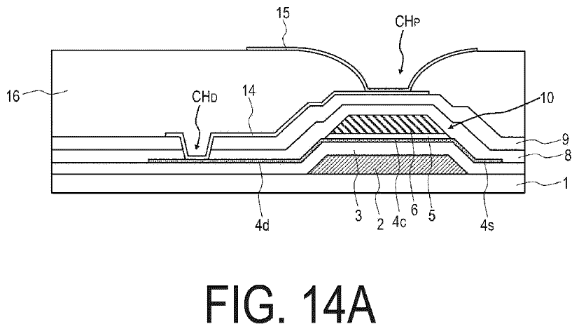

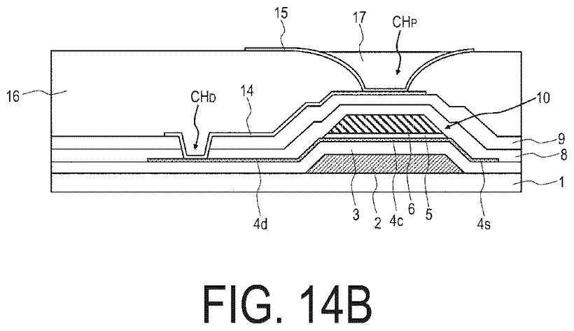

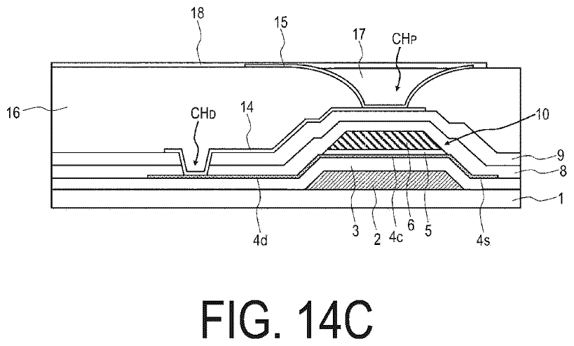

Subsequently, as illustrated in FIG. 14A, the second connection electrode 15 is formed on the first flattened layer 16 and in the pixel contact hole CH_{P}. For example, a transparent conductive film is deposited by sputtering, and then the transparent conductive film is patterned by a photolithography process, thereby forming the second connection electrode 15. As a transparent conductive material for forming the second connection electrode 15, for example, indium tin oxide or indium zinc oxide can be used. A thickness of the second connection electrode 15 is, for example, 30 nm or more and 100 nm or less.

When misalignment occurs in the photolithography process during forming the second connection electrode 15, the finish of the second connection electrode 15 may vary. When the second connection electrode 15 and the pixel electrode 18 are formed from the same transparent conductive material, even when a portion of the second connection electrode 15 protrudes from a region where the pixel electrode 18 is formed, the protruding portion is removed when the transparent conductive film for the pixel electrode 18 is patterned (etched). That is, the second connection electrode 15 can be patterned in a self-alignment manner to have the same size as the mask pattern of the pixel electrode 18.

As already described, indium tin oxide or indium zinc oxide can be used as a material for the second connection electrode 15. However, indium tin oxide crystallizes due to a thermal history during the process and is less likely to dissolve. In contrast, indium zinc oxide is likely to maintain an amorphous state even when subjected to a thermal history, and can be easily dissolved with a PAN based etchant. Therefore, it is preferable to use indium zinc oxide as the material for the second connection electrode 15 (hereinafter, referred to as a “first measure”).

When indium tin oxide is used as the material for the second connection electrode 15, it is preferable to make the size of the second connection electrode 15 smaller than or equal to a value of a process margin relative to the size of the pixel electrode 18 (hereinafter, referred to as a “second measure”). Thus, even when misalignment occurs in each of the second connection electrode 15 and the pixel electrode 18, protrusion of a portion of the second connection electrode 15 from the region where the pixel electrode 18 is formed can be suppressed.

Since the sum of areas of the second connection electrode 15 and the pixel electrode 18 functions as an effective pixel electrode (here, simply referred to as a pixel electrode), both the first measure and the second measure can prevent the pixel electrode area from becoming larger than necessary. That is, not only can the parasitic capacitance between the source electrode 7 and the pixel electrode be reduced, but also variations in parasitic capacitance caused by variations in the positions of the second connection electrode 15 and the source electrode 7 can be avoided (this is because the pixel electrode 18 is larger than or equal in size to the second connection electrode 15, so that when misalignment occurs, the second connection electrode 15 can be prevented from protruding from the pixel electrode 18 and coming closer to the source electrode 7, thereby preventing an increase in parasitic capacitance).

Subsequently, as illustrated in FIG. 14B, the second flattened layer 17 is formed to fill the pixel contact hole CH_{P}. For example, by applying a photosensitive resin material and sequentially performing exposure, development, and post-baking, the second flattened layer 17 is obtained. As the photosensitive resin material, for example, a photosensitive acrylic resin can be used. As already described, by using a multi-tone photomask as a photomask during exposure, the pixel contact hole CH_{P} can be filled with the second flattened layer 17 with high accuracy.

Subsequently, as illustrated in FIG. 14C, the pixel electrode 18 is formed on the first flattened layer 16, the second flattened layer 17, and the second connection electrode 15. For example, a transparent conductive film is deposited by sputtering, and then the transparent conductive film is patterned by a photolithography process, thereby forming the pixel electrode 18. As a transparent conductive material for forming the pixel electrode 18, for example, indium tin oxide or indium zinc oxide can be used. Here, indium zinc oxide is used. A thickness of the pixel electrode 18 is, for example, 30 nm or more and 100 nm or less.

Subsequently, a dielectric layer is formed to cover the pixel electrode. For example, the dielectric layer can be formed by CVD. As the dielectric layer, for example, an inorganic insulating layer similar to the first interlayer insulating layer 8 and the second interlayer insulating layer 9 can be used. Here, a silicon nitride layer is used as the dielectric layer. A thickness of the dielectric layer is, for example, 50 nm or more and 300 nm or less.

Thereafter, the common electrode is formed on the dielectric layer. For example, a transparent conductive film is deposited by sputtering, and then the transparent conductive film is patterned by a photolithography process, thereby forming the common electrode. As a transparent conductive material for forming the common electrode, for example, indium tin oxide or indium zinc oxide can be used. Here, indium zinc oxide is used. A thickness of the common electrode is, for example, 30 nm or more and 100 nm or less. In this manner, the active matrix substrate 100 is obtained.

Note that, when a pixel pitch is large enough to provide a sufficient interval between the source electrode 7 and the first connection electrode 14, the first connection electrode 14 may be provided in the same layer as the source electrode 7 (i.e., on the first interlayer insulating layer 8). In that case, the second interlayer insulating layer 9 can be omitted to simplify the manufacturing process.

As already described, in the active matrix substrate 100 according to the present embodiment, the side surface 16s of the pixel contact hole CH_{P} has a relatively gentle tapered shape. The shape of the side surface 16s of the pixel contact hole CH_{P} can be controlled, for example, by adjusting temperature and time of the post-baking (hereinafter, collectively referred to as “thermal history”). To be specific, the smaller the thermal history is, the steeper the tapered shape can be made, and the larger the thermal history is, the gentler the tapered shape can be made. Therefore, by making the thermal history of the post-baking sufficiently large, the pixel contact hole CH_{P} having the side surface 16s with a relatively gentle tapered shape can be formed. By making the thermal history sufficiently large, it is also possible to barely change the shape of the side surface 16s after the post-baking.

When the photosensitive acrylic resin exemplified above is used as the material for the first flattened layer 16, from the viewpoint of making the tapered shape of the side surface 16s sufficiently gentle, the post-baking is preferably performed, for example, at 200° C. or higher for 30 minutes or longer. In addition, by making the thermal history sufficiently large, an effect of eliminating moisture contained in the photosensitive resin material is also obtained, which suppresses film floating when the film is deposited on the first flattened layer 16 in a subsequent step, thereby improving adhesion.

The thermal history required to make the tapered shape sufficiently gentle varies depending on the photosensitive resin material used as the material for the first flattened layer 16. In order to make the tapered shape of the side surface 16s of the pixel contact hole CH_{P} gentle, it is also preferable to use, as the material for the first flattened layer 16, a photosensitive resin material that is relatively easy to cause shape change by post-baking. When a material that is relatively easy to cause shape change by post-baking is used, the thermal history may be outside the above-described preferable range (200° C. or higher for 30 minutes or longer).

Note that, in active matrix substrates for high-definition liquid crystal display devices, when the side surface of the pixel contact hole has a gentle tapered shape, the effective opening diameter becomes large. Therefore, it has been preferred to form the pixel contact hole so that the side surface has a steep taper. In contrast, in the active matrix substrate 100 according to the present embodiment, the tapered shape of the side surface 16s of the pixel contact hole CH_{P} is intentionally made gentle, thereby achieving the above-described effect.

The shape of the upper face 17t of the second flattened layer 17 can also be controlled by adjusting the thermal history (temperature and time) of the post-baking when forming the second flattened layer 17. To be specific, the larger the thermal history is, the flatter the upper face 17t of the second flattened layer 17 can be.

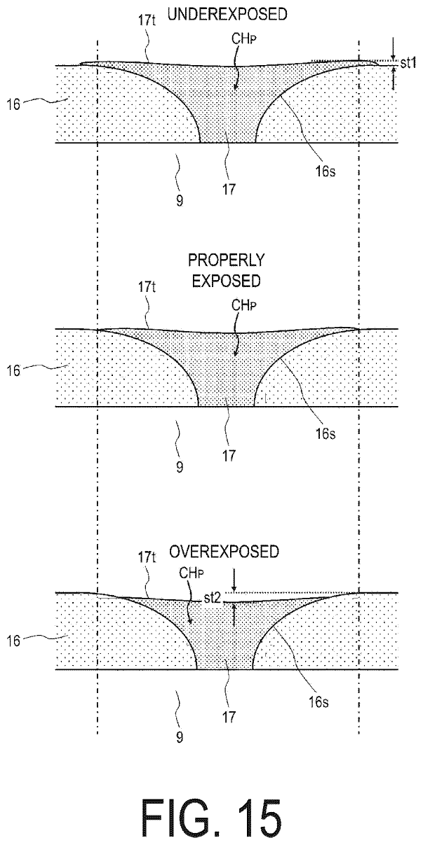

FIG. 15 illustrates examples of cross-sectional shapes of the second flattened layer 17 when the thermal history of the post-baking during formation of the second flattened layer 17 is sufficiently large. An upper part, a middle part, and a lower part of FIG. 15 illustrate cases of underexposure, proper exposure, and overexposure, respectively. As can be seen from FIG. 15, by making the thermal history sufficiently large, the second flattened layer 17 changes shape to follow the tapered shape of the side surface 16s of the pixel contact hole CH_{P}, so that the upper face 17t of the second flattened layer 17 becomes flatter, and the steps (the step st1 formed in the vicinity of the periphery of the pixel contact hole CH_{P} and the step st2 formed in the pixel contact hole CH_{P}) can be reduced even when the exposure amount varies.

It is also preferable to use, as the material for the second flattened layer 17, a photosensitive resin material that is relatively easy to cause shape change by post-baking.

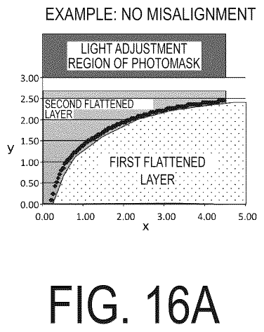

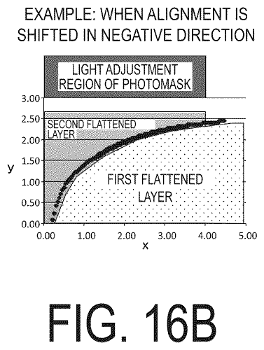

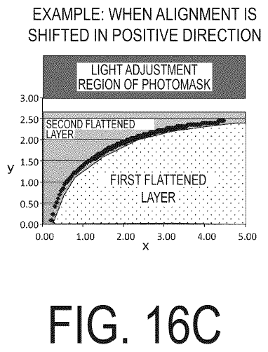

FIGS. 16A, 16B, and 16C are scatter plots (graphs) plotting the tapered shapes of the side surface 16s of the pixel contact hole CH_{P} of an actual prototype of the active matrix substrate 100 according to the present embodiment (hereinafter, referred to as “Example”). FIG. 16A shows a case where no misalignment of the multi-tone photomask occurs. FIG. 16B shows a case where the alignment of the multi-tone photomask is shifted in a negative direction (left in the figure), and FIG. 16C shows a case where the alignment of the multi-tone photomask is shifted in a positive direction (right in the figure).

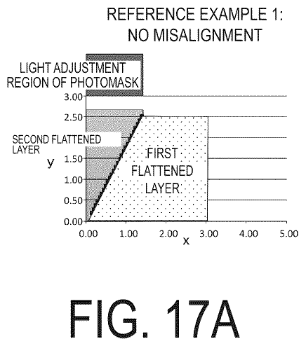

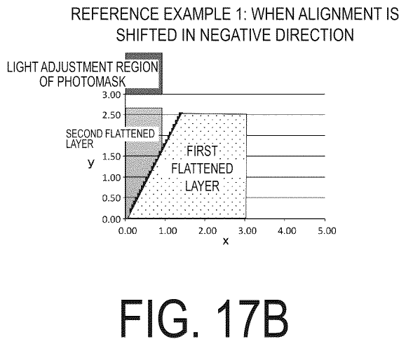

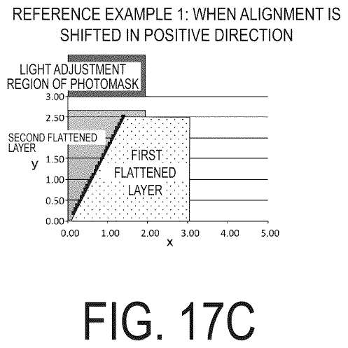

FIGS. 17A, 17B, and 17C are scatter plots (graphs) of the side shapes of the pixel contact hole CH_{P} formed so that the tapered shape of the side surface 16s is steep (the equivalent circle diameter d2 of the upper face 17t of the second flattened layer 17 is less than three times the equivalent circle diameter d1 of the bottom face 16s of the pixel contact hole CH_{P}) (hereinafter, referred to as Reference Example 1). FIG. 17A shows a case where no misalignment of the multi-tone photomask occurs. FIG. 17B shows a case where the alignment of the multi-tone photomask is shifted in the negative direction (left in the figure), and FIG. 17C shows a case where the alignment of the multi-tone photomask is shifted in the positive direction (right in the figure).

By forming the second flattened layer 17 using the multi-tone photomask, when misalignment of the multi-tone photomask does not occur, it is possible to prevent the second flattened layer 17 in the pixel contact hole CH_{P} from being reduced more than necessary in both Example and Reference Example 1 as shown in FIGS. 16A and 17A.

On the other hand, when the alignment of the multi-tone photomask is shifted in the negative direction, in Reference Example 1, a large step (a portion where the second flattened layer 17 does not completely cover the side surface 16s of the pixel contact hole CH_{P}) is formed in the pixel contact hole CH_{P}, as shown in FIG. 17B. In contrast, in Example, as shown in FIG. 16B, a step formed in the pixel contact hole CH_{P} is small.

When the alignment of the multi-tone photomask is shifted in the positive direction, the second flattened layer 17 spreads outside the pixel contact hole CH_{P} in both Example and Reference Example 1, as shown in FIGS. 16C and 17C. However, on the side opposite to that shown in the figure, a phenomenon similar to that occurs when the alignment is shifted in the negative direction. That is, in Reference Example 1, a large step is formed in the pixel contact hole CH_{P}, whereas in Example, a step formed in the pixel contact hole CH_{P} is small.

As can be seen from the description made with reference to FIGS. 16A to 17C, the amount of change in a height (depth) direction (amount of change in a y direction) corresponding to the amount of misalignment of the multi-tone photomask (amount of change in an x direction) occurs at an end of the light adjustment region of the multi-tone photomask, which can result in a step. At such a position, the height change due to misalignment, that is, the differential change amount differs greatly between a tapered shape approximated by a logarithmic curve as shown in FIGS. 16A to 16C, and a tapered shape approximated by a straight line having a much steeper slope as shown in FIGS. 17A to 17C. This causes the above-described difference between Example and Reference Example 1.

Note that, although a case where misalignment of the multi-tone photomask occurs is shown here as an example, a similar effect can be obtained for influence of changes in the opening diameter of the pixel contact hole CH_{P} and changes in the diameter of the second flattened layer 17 caused by exposure variation. Accordingly, by adopting the structure such as the active matrix substrate 100 according to the present embodiment, it is possible to reduce differences in the finish of the shape of the second flattened layer 17 that may occur due to process variations when forming the second flattened layer 17.

Note that, in the pixel contact hole CH_{P} having a steeply tapered side surface 16s, the following measures are considered to prevent a step from occurring in the pixel contact hole CH_{P}.

(A) A width of the light adjustment region of the multi-tone photomask is set to be larger than the finished width that may occur due to process variations when forming the first flattened layer 16 and the second flattened layer 17, thereby ensuring that the second flattened layer 17 completely covers the side surface 16s of the pixel contact hole CH_{P} under all circumstances.

(B) By making the upper face 17t of the second flattened layer 17 sufficiently higher than the flat region F of the first flattened layer 16, even when a step occurs in the pixel contact hole CH_{P}, the second flattened layer 17 is deformed during post-baking so as to fill the step.

(C) Measures (A) and (B) are used in combination.

When measure (A) can be easily implemented, only measure (A) will be employed. However, a result of actual studies by the inventors shows that it is difficult to stably form the second flattened layer 17 such that the upper face 17t is at the same height as the flat region F using only measure (A) due to the influence of process variations, and therefore measure (C) is necessary. That is, in the pixel contact hole CH_{P} having a steeply tapered side surface 16s, when attempting to suppress the formation of a step in the pixel contact hole CH_{P}, the height of the upper face 17t of the second flattened layer 17 tends to be higher (i.e., the protrusion height of the second flattened layer 17 relative to the first flattened layer 16 tends to be larger).

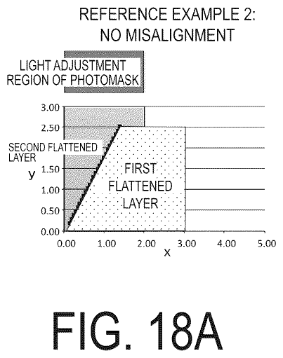

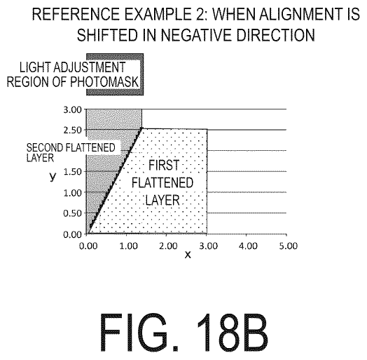

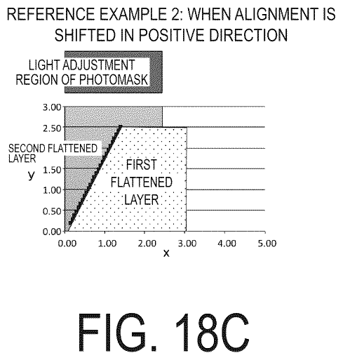

FIGS. 18A, 18B, and 18C are scatter plots (graphs) plotting the side shapes of the pixel contact hole CH_{P} of Reference Example 1 to which measure (C) is applied (hereinafter, referred to as Reference Example 2). FIG. 18A shows a case where no misalignment of the multi-tone photomask occurs. FIG. 18B shows a case where the alignment of the multi-tone photomask is shifted in the negative direction (left in the figure), and FIG. 18C shows a case where the alignment of the multi-tone photomask is shifted in the positive direction (right in the figure).

In Reference Example 2, as shown in FIGS. 18A, 18B, and 18C, in all cases where there is no misalignment, where there is a misalignment in the negative direction, and where there is a misalignment in the positive direction, no step is formed in the pixel contact hole CH_{P}, but the protrusion height of the second flattened layer 17 relative to the first flattened layer 16 is large.

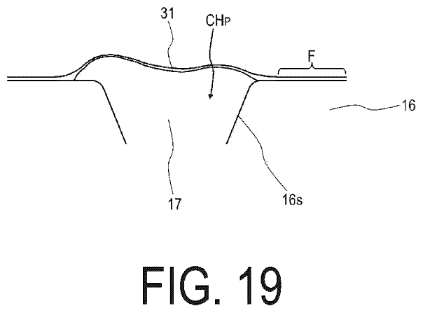

FIG. 19 is a schematic view created based on a cross-sectional observation of the pixel contact hole CH_{P} in Reference Example 2. As can be seen from FIG. 19, the tapered shape of the side surface 16s of the pixel contact hole CH_{P} is extremely steep. Due to the misalignment during forming the second flattened layer 17, the second flattened layer 17 is shifted slightly to the left in the figure, so that of the two protruding portions of the second flattened layer 17, the left protruding portion is higher than the right protruding portion. In this configuration, it can be seen that there is a difference in thickness of an alignment film 31 between the periphery of the step and the flat region F. To be specific, it can be seen that the alignment film 31 is relatively thin on the protruding portions of the second flattened layer 17 and on the flat region F, whereas the alignment film 31 is relatively thick in the vicinities of the base ends of the protruding portions of the second flattened layer 17 due to accumulation of an alignment film material. When the thickness of the alignment film 31 is not uniform as described above, the alignment state of the liquid crystal layer changes, which may adversely affect optical characteristics, such as image sticking or unevenness.

Note that, although a cross-sectional observation image is not shown here, as illustrated in FIG. 8D, when the second flattened layer 17 is reduced more than necessary (i.e., when the upper face 17t of the second flattened layer 17 is lower than the flat region F), a large amount of the alignment film material flows into the pixel contact hole CH_{P}, and the difference in thicknesses of the alignment film 31 becomes even larger.

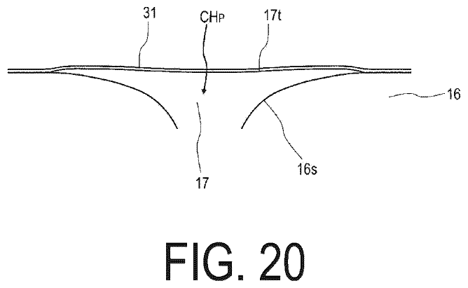

FIG. 20 is a schematic view created based on a cross-sectional observation of the pixel contact hole CH_{P} in Example. As can be seen from FIG. 20, the tapered shape of the side surface 16s of the pixel contact hole CH_{P} is gentle. It can also be seen that the shape of the upper face 17t of the second flattened layer 17 is almost the same on the left and right, and there is almost no difference in height between the left and right. This is because the second flattened layer 17 is formed to follow the tapered shape of the side surface 16s of the pixel contact hole CH_{P}, and it is considered that there is a positive correlation between the magnitude of the inclination of the tapered shape and the magnitude of the size change in the height direction of the second flattened layer 17 caused by the misalignment. In Example, since the step is small, it can be seen that the thickness of the alignment film 31 is relatively uniform.

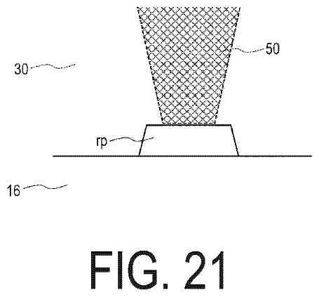

Note that, when forming the second flattened layer 17, the photosensitive resin material may be left in an island shape or a band shape on the first flattened layer 16 to form a structure (hereinafter, referred to as a “spacer receiving portion”) rp for receiving a columnar spacer (also may be referred to as a “photospacer” or a “PS”) 50, as illustrated in FIG. 21. The columnar spacer 50 is provided in a counter substrate 600, which will be described later, on a liquid crystal layer 30 side. The spacer receiving portion rp is disposed in a region corresponding to the columnar spacer 50. Note that, although not illustrated here, a dielectric layer and a common electrode may be formed on the spacer receiving portion rp. Further, when designing the mask, by changing the settings of the intermediate exposure described above, it is possible to mix the spacer receiving portions rp having different heights, thereby optimizing the cell thickness and improving the strength during a pressure test and the display quality.

### Second Embodiment

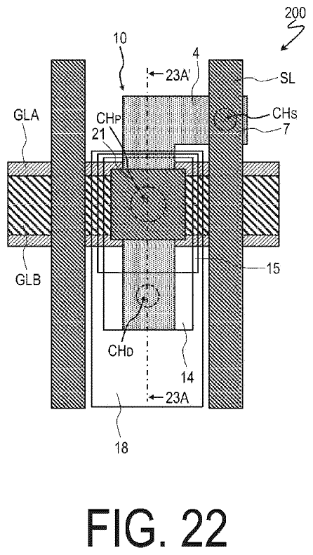

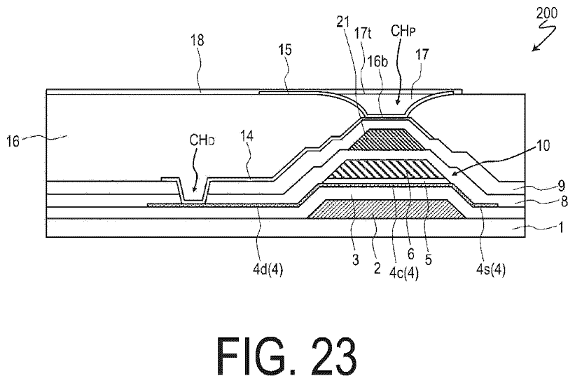

An active matrix substrate 200 according to the present embodiment will be described with reference to FIGS. 22 and 23. FIG. 22 is a plan view schematically illustrating the active matrix substrate 200. FIG. 23 is a cross-sectional view schematically illustrating the active matrix substrate 200, taken along line 23A-23A′ in FIG. 22. In the following, description will focus on points where the active matrix substrate 200 differs from the active matrix substrate 100 according to the first embodiment.

In the active matrix substrate 200 according to the present embodiment, as illustrated in FIGS. 22 and 23, an island-shaped electrode 21 is provided in the same layer as a source electrode 7 (by patterning the same conductive film) and separated from the source electrode 7. That is, a source metal layer includes the island-shaped electrode 21 in addition to the source electrode 7 and a source wiring line SL.

When viewed from a normal direction of a substrate 1, a bottom face 16b of a pixel contact hole CH_{P} overlaps, at least partially, both a lower gate metal layer and an upper gate metal layer (to be more specific, both a lower gate electrode 2 and an upper gate electrode 6). In the present embodiment, the bottom face 16b of the pixel contact hole CH_{P} also overlaps, at least partially, the source metal layer. To be more specific, the bottom face 16b of the pixel contact hole CH_{P} overlaps, at least partially, the island-shaped electrode 21. In the illustrated example, the bottom face 16b of the pixel contact hole CH_{P} as a whole overlaps the island-shaped electrode 21.

As described above, in the active matrix substrate 200 according to the present embodiment, the bottom face 16b of the pixel contact hole CH_{P} formed in a flattened layer 16 overlaps, at least partially, not only the lower gate electrode 2 and the upper gate electrode 6, but also the island-shaped electrode 21. This makes it possible to reduce an opening diameter of the pixel contact hole CH_{P}.

### Third Embodiment

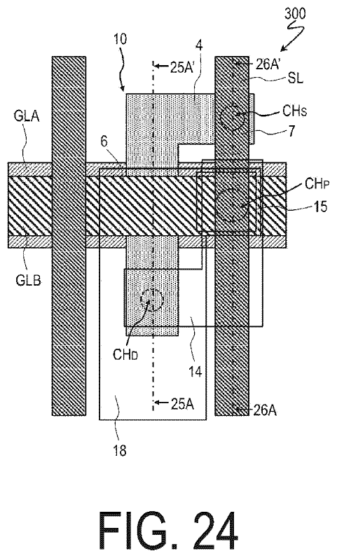

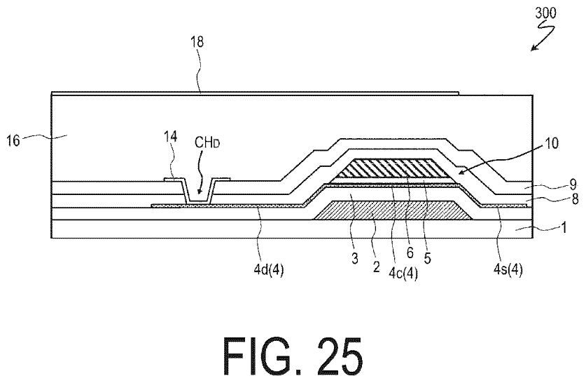

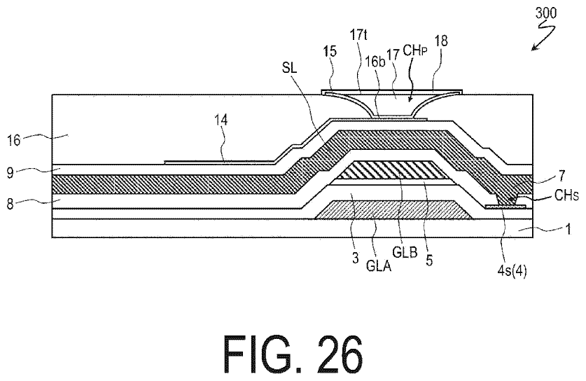

An active matrix substrate 300 according to the present embodiment will be described with reference to FIGS. 24, 25, and 26. FIG. 24 is a plan view schematically illustrating the active matrix substrate 300. FIGS. 25 and 26 are cross-sectional views schematically illustrating the active matrix substrate 300, taken along lines 25A-25A′ and 26A-26A′ in FIG. 24, respectively. In the following, description will focus on points where the active matrix substrate 300 differs from the active matrix substrate 100 according to the first embodiment.

In the active matrix substrate 300 according to the present embodiment, when viewed from a normal direction of a substrate 1, a bottom face 16b of a pixel contact hole CH_{P} overlaps, at least partially, both a lower gate wiring line GLA and an upper gate wiring line GLB. In the illustrated example, the bottom face 16b of pixel contact hole CH_{P} as a whole overlaps both the lower gate wiring line GLA and the upper gate wiring line GLB.

The bottom face 16b of the pixel contact hole CH_{P} overlaps, at least partially, both the lower gate wiring line GLA and the upper gate wiring line GLB as described above, which also allows an opening diameter of pixel contact hole CH_{P} to be reduced, thereby improving transmittance.

Note that, when viewed from the normal direction of the substrate 1, in a case where the bottom face 16b of the pixel contact hole CH_{P} overlaps, at least partially, at least the lower gate wiring line GLA out of the lower gate wiring line GLA and the upper gate wiring line GLB, an effect of reducing the opening diameter of the pixel contact hole CH_{P} and improving transmittance can be obtained. However, from the viewpoint of further improving transmittance, it is preferable that the bottom face 16b of the pixel contact hole CH_{P} overlap, at least partially, both the lower gate wiring line GLA and the upper gate wiring line GLB, and it is more preferable that the bottom face 16b of the pixel contact hole CH_{P} as a whole overlap both the lower gate wiring line GLA and the upper gate wiring line GLB.

Further, in the active matrix substrate 300 according to the present embodiment, when viewed from the normal direction of the substrate 1, the bottom face 16b of the pixel contact hole CH_{P} also overlaps a source wiring line SL, at least partially (as a whole in the illustrated example). This makes it possible to reduce an opening diameter of the pixel contact hole CH_{P}.

### Fourth Embodiment

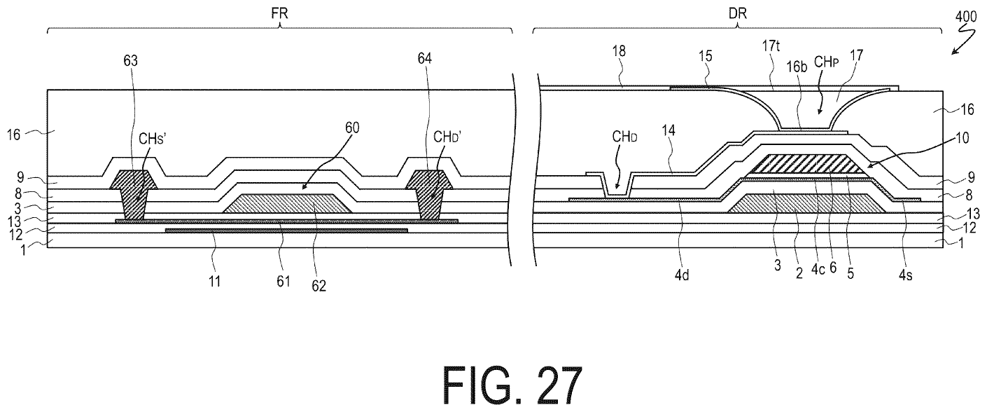

An active matrix substrate 400 according to the present embodiment will be described with reference to FIG. 27. FIG. 27 is a cross-sectional view schematically illustrating the active matrix substrate 400. A part of a display region DR is illustrated on a right side in FIG. 27, and a part of a non-display region FR is illustrated on a left side in FIG. 27. In the following, description will focus on points where the active matrix substrate 400 differs from the active matrix substrate 100 according to the first embodiment.

As illustrated in FIG. 27, the active matrix substrate 400 includes a first TFT 10 and a second TFT 60 supported by a substrate 1. The TFT 10 is a pixel TFT disposed in each pixel region P of the display region DR and is an oxide semiconductor TFT that includes an oxide semiconductor layer 4 as an active layer. A structure of the display region DR of the active matrix substrate 400 is substantially the same as the structure of the display region DR of the active matrix substrate 100 according to the first embodiment (or the structure of the display region DR of the active matrix substrate 200 or 300 according to the second or third embodiment).

The second TFT 60 is provided in the non-display region. The second TFT 60 is a crystalline silicon TFT that includes a crystalline silicon semiconductor layer 61 as an active layer. The second TFT 60 is a circuit TFT that configures a peripheral circuit, for example, a gate driver monolithic (GDM) circuit or a source shared driving (SSD) circuit. The second TFT 60 includes, in addition to the crystalline silicon semiconductor layer 61 described above, a gate electrode 62, a source electrode 63, and a drain electrode 64.

In the present embodiment, the crystalline silicon semiconductor layer 61 is a polycrystalline silicon layer (e.g., a low-temperature polysilicon (LTPS) layer). In the illustrated example, a base coat layer (underlayer) 12 is provided on the substrate 1, and the crystalline silicon semiconductor layer 61 is provided on the base coat layer 12.

The gate electrode 62 is provided on an insulating layer 13 that covers the crystalline silicon semiconductor layer 61, and faces the crystalline silicon semiconductor layer 61 with the insulating layer 13 interposed therebetween. The gate electrode 62 is formed in the same layer as a lower gate electrode 2 of the first TFT 10 (i.e., by patterning the same conductive film). The insulating layer 13 is formed from an inorganic insulating material similar to an inorganic insulating material that forms a lower gate insulating layer 3 and the like.

The source electrode 63 and the drain electrode 64 are formed in the same layer as a source electrode 7 of the first TFT 10 (i.e., by patterning the same conductive film). Accordingly, the source electrode 63 and the drain electrode 64 are provided on a first interlayer insulating layer 8. The source electrode 63 and the drain electrode 64 are connected to the crystalline silicon semiconductor layer 61 in a source contact hole CH_{S}′ and a drain contact hole CH_{D}′ formed in the first interlayer insulating layer 8, the lower gate insulating layer 3, and the insulating layer 13, respectively.

As described above, the second TFT 60 has a top gate structure. A light blocking layer 11 formed under the base coat layer 12 blocks light from reaching a channel region of the crystalline silicon semiconductor layer 61 of the second TFT 60 (a region facing the gate electrode 62).

As described, in the present embodiment, by using an oxide semiconductor TFT having excellent off-leakage characteristics as the pixel TFT 10 and using a crystalline silicon TFT having excellent mobility as the circuit TFT 60, it is possible to improve drive capability while reducing power consumption. As exemplified, the gate electrode 62 of the circuit TFT 60 is formed in the same layer as the lower gate electrode 2 of the pixel TFT 10, thereby suppressing an increase in the number of manufacturing steps.

### Oxide Semiconductor

An oxide semiconductor included in the oxide semiconductor layer 4 may be an amorphous oxide semiconductor, or may be a crystalline oxide semiconductor including a crystalline portion. Examples of the crystalline oxide semiconductor include a polycrystalline oxide semiconductor, a microcrystalline oxide semiconductor, and a crystalline oxide semiconductor having a c-axis oriented substantially perpendicular to the layer surface.

The oxide semiconductor layer 4 may have a layered structure including two or more layers. The oxide semiconductor layer 4 having a layered structure may include an amorphous oxide semiconductor layer and a crystalline oxide semiconductor layer, and may include a plurality of crystalline oxide semiconductor layers having different crystal structures. In addition, the oxide semiconductor layer 4 having a layered structure may include a plurality of amorphous oxide semiconductor layers. When the oxide semiconductor layer 4 has a layered structure, energy gaps of the respective layers may be different from each other.

Materials, structures, and film formation methods of an amorphous oxide semiconductor and the above-described each of crystalline oxide semiconductors, a configuration of an oxide semiconductor layer having a layered structure, and the like are described in, for example, JP 2014-007399 A. The entire contents of the disclosure of JP 2014-007399 A are incorporated herein by reference.

The oxide semiconductor layer 4 may include, for example, at least one metal element among In, Ga, and Zn. In the above-described embodiments, the oxide semiconductor layer 4 includes, for example, an In—Ga—Zn—O based semiconductor (for example, indium gallium zinc oxide). Here, the In—Ga—Zn—O based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. Such an oxide semiconductor layer 4 can be formed of an oxide semiconductor film including an In—Ga—Zn—O based semiconductor.

The In—Ga—Zn—O based semiconductor may be an amorphous semiconductor or may be a crystalline semiconductor. A crystalline In—Ga—Zn—O based semiconductor in which a c-axis is oriented substantially perpendicular to a layer surface is preferable as the crystalline In—Ga—Zn—O based semiconductor.

Note that a crystal structure of the crystalline In—Ga—Zn—O based semiconductor is disclosed in, for example, JP 2014-007399 A as described above, JP 2012-134475 A, and JP 2014-209727 A. The entire contents of the disclosure of JP 2012-134475 A and JP 2014-209727 A are incorporated herein by reference. A TFT including an In—Ga—Zn—O based semiconductor layer has a high mobility (more than 20 times as compared to an a-Si TFT) and a low leakage current (less than 1/100 as compared to the a-Si TFT). Thus, such a TFT can be suitably used as a drive TFT (for example, a TFT included in a drive circuit provided in a periphery of a display region including a plurality of pixels, and on the same substrate as the display region) and a pixel TFT (TFT provided in a pixel).

In place of the In—Ga—Zn—O based semiconductor, the oxide semiconductor layer 4 may include another oxide semiconductor. There may be included, for example, an In—Sn—Zn—O based semiconductor (for example, In₂O₃—SnO₂—ZnO; InSnZnO). The In—Sn—Zn—O based semiconductor is a ternary oxide of In (indium), Sn (tin), and Zn (zinc). Alternatively, the oxide semiconductor layer 4 may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, and an In—Ga—Zn—Sn—O based semiconductor.

### Liquid Crystal Display Device

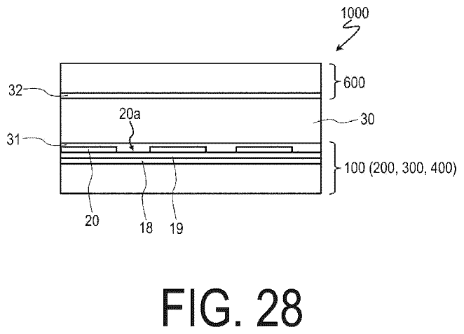

The active matrix substrates 100, 200, 300, and 400 according to the embodiments of the disclosure can be suitably used in liquid crystal display devices. An example of the liquid crystal display device is illustrated in FIG. 28.

A liquid crystal display device 1000 illustrated in FIG. 28 includes the active matrix substrate 100 (or the active matrix substrate 200, 300, or 400), a counter substrate 600 provided so as to face the active matrix substrate 100, and a liquid crystal layer 30 provided between the active matrix substrate 100 and the counter substrate 600.

The active matrix substrate 100 includes the TFTs 10 (not illustrated here) disposed in the pixel regions P, respectively, the pixel electrodes 18 electrically connected to the TFTs 10, respectively, the dielectric layer 19 provided so as to cover the pixel electrodes 18, and the common electrode 20 provided on the dielectric layer 19 and facing the pixel electrodes 18. At least one slit 20a is formed in the common electrode 20 for each pixel region P.

Alignment films 31 and 32 are provided on the outermost surfaces of the active matrix substrate 100 and the counter substrate 600 on the liquid crystal layer 30 side, respectively. The counter substrate 600 typically includes a color filter layer and a black matrix (neither of which are illustrated).

A thickness (cell gap) of the liquid crystal layer 30 is defined by columnar spacers 50 (not illustrated in FIG. 28) provided in the counter substrate 600 on the liquid crystal layer 30 side. Spacer receiving portions rp illustrated in FIG. 21 may be provided on the active matrix substrate side.

Note that, although the liquid crystal display device 1000 in an FFS mode, which is a type of transverse electrical field mode, is exemplified here, the active matrix substrates according to the embodiments of the disclosure may be used for liquid crystal display devices in other display modes. In a liquid crystal display device of a vertical electrical field mode such as a twisted nematic (TN) mode or a vertical alignment (VA) mode, a common electrode is provided on a counter substrate side.

### INDUSTRIAL APPLICABILITY

According to the embodiments of the disclosure, it is possible to provide active matrix substrates capable of suppressing a decrease in transmittance caused by a contact hole formed in a flattened layer. The active matrix substrate according to the embodiments of the disclosure is suitably used in a high-resolution (for example, 1000 ppi or more) liquid crystal display device such as a liquid crystal display device for a head-mounted display.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An active matrix substrate comprising:
a display region defined by multiple pixel regions;
a substrate;
first TFTs supported by the substrate and disposed in the multiple pixel regions, respectively;
a first flattened layer covering the first TFTs; and
pixel electrodes provided on the first flattened layer and electrically connected to the first TFTs, respectively, each of the first TFTs including a lower gate electrode provided on the substrate, a lower gate insulating layer covering the lower gate electrode, an oxide semiconductor layer provided on the lower gate insulating layer, the oxide semiconductor layer including a channel region facing the lower gate electrode with the lower gate insulating layer interposed between the channel region and the lower gate electrode, and a source contact region located on one side of the channel region and a drain contact region located on another side of the channel region, an upper gate insulating layer provided on the channel region of the oxide semiconductor layer, and an upper gate electrode provided on the upper gate insulating layer and facing the channel region of the oxide semiconductor layer with the upper gate insulating layer interposed between the upper gate electrode and the channel region,
wherein the active matrix substrate includes first connection electrodes located under the first flattened layer, each of the first connection electrodes electrically connecting the drain contact region of the oxide semiconductor layer and each of the pixel electrodes,
the first flattened layer includes pixel contact holes formed such that a portion of each of the first connection electrodes is exposed,
as viewed from a normal direction of the substrate, a bottom face of each of the pixel contact holes overlaps, at least partially, at least a lower gate metal layer out of the lower gate metal layer including the lower gate electrode and an upper gate metal layer including the upper gate electrode,
the first connection electrodes are formed from a transparent conductive material,
the active matrix substrate further includes second connection electrodes formed from a transparent conductive material, each of the second connection electrodes electrically connecting each of the first connection electrodes and each of the pixel electrodes, and each of the second connection electrodes being in contact with each of the first connection electrodes in each of the pixel contact holes, and second flattened layers formed such that each of the pixel contact holes is filled with each of the second flattened layers, the second flattened layer covering a portion of each of the second connection electrodes, and
a ratio of an equivalent circle diameter d2 of an upper face of each of the second flattened layers to an equivalent circle diameter d1 of a bottom face of each of the pixel contact holes is three or more and five or less.

2. The active matrix substrate according to claim 1,
wherein in a cross section parallel to the normal direction of the substrate, in a case where an axis orthogonal to the normal direction of the substrate is defined as an x-axis, an axis parallel to the normal direction of the substrate is defined as a y-axis, and the lowest point of a side surface of each of the pixel contact holes is located on the x-axis in a range of x>0, the side surface of each of the pixel contact holes has a shape approximated by the following equation (1)
y=A*ln(x)+B (1)
where units of the x-axis and the y-axis are each μm, and 0.70≤A≤0.80, and B>0 are satisfied.

3. The active matrix substrate according to claim 1,
wherein in a case where a region of an upper face of the first flattened layer in which the pixel contact holes are not formed is referred to as a flat region, a difference between a height of the highest portion of the upper face of each of the second flattened layers and a height of the flat region is 0.5 μm or less.

4. The active matrix substrate according to claim 1,
wherein each of the pixel electrodes is in contact with a portion of each of the second connection electrodes not covered with each of the second flattened layers, and
each of the pixel electrodes includes a portion located on each of the second flattened layers.

5. The active matrix substrate according to claim 1,
wherein as viewed from the normal direction of the substrate, the bottom face of each of the pixel contact holes overlaps, at least partially, at least the lower gate electrode out of the lower gate electrode and the upper gate electrode.

6. The active matrix substrate according to claim 1,
wherein the lower gate metal layer includes a lower gate wiring line electrically connected to the lower gate electrode,
the upper gate metal layer includes an upper gate wiring line electrically connected to the upper gate electrode, and
as viewed from the normal direction of the substrate, the bottom face of each of the pixel contact holes overlaps, at least partially, at least the lower gate wiring line out of the lower gate wiring line and the upper gate wiring line.

7. The active matrix substrate according to claim 1,
wherein as viewed from the normal direction of the substrate, the bottom face of each of the pixel contact holes overlaps, at least partially, both the lower gate metal layer and the upper gate metal layer.

8. The active matrix substrate according to claim 7,
wherein as viewed from the normal direction of the substrate, the bottom face of each of the pixel contact holes overlaps, at least partially, both the lower gate electrode and the upper gate electrode.

9. The active matrix substrate according to claim 7,
wherein the lower gate metal layer includes a lower gate wiring line electrically connected to the lower gate electrode,
the upper gate metal layer includes an upper gate wiring line electrically connected to the upper gate electrode, and
as viewed from the normal direction of the substrate, the bottom face of each of the pixel contact holes overlaps, at least partially, both the lower gate wiring line and the upper gate wiring line.

10. The active matrix substrate according to claim 1,
wherein as viewed from the normal direction of the substrate, the bottom face of each of the pixel contact holes as a whole overlaps both the lower gate metal layer and the upper gate metal layer.

11. The active matrix substrate according to claim 10,
wherein as viewed from the normal direction of the substrate, the bottom face of each of the pixel contact holes as a whole overlaps both the lower gate electrode and the upper gate electrode.

12. The active matrix substrate according to claim 10,
wherein the lower gate metal layer includes a lower gate wiring line electrically connected to the lower gate electrode,
the upper gate metal layer includes an upper gate wiring line electrically connected to the upper gate electrode, and
as viewed from the normal direction of the substrate, the bottom face of each of the pixel contact holes as a whole overlaps both the lower gate wiring line and the upper gate wiring line.

13. The active matrix substrate according to claim 1,
wherein each of the first TFTs includes a source electrode electrically connected to the source contact region, and
as viewed from the normal direction of the substrate, the bottom face of each of the pixel contact holes overlaps, at least partially, a source metal layer including the source electrode.

14. The active matrix substrate according to claim 13,
wherein the source metal layer includes an island-shaped electrode provided separated from the source electrode, and
as viewed from the normal direction of the substrate, the bottom face of each of the pixel contact holes overlaps, at least partially, the island-shaped electrode.

15. The active matrix substrate according to claim 13,
wherein the source metal layer includes a source wiring line electrically connected to the source electrode, and
as viewed from the normal direction of the substrate, the bottom face of each of the pixel contact holes overlaps, at least partially, the source wiring line.

16. The active matrix substrate according to claim 1,
wherein a portion of each of the first connection electrodes is in contact with the drain contact region of the oxide semiconductor layer.

17. The active matrix substrate according to claim 1,
wherein the second connection electrodes and the pixel electrodes are formed from the same transparent conductive material.

18. The active matrix substrate according to claim 17,
wherein the second connection electrodes and the pixel electrodes are formed from indium zinc oxide.

19. The active matrix substrate according to claim 1,
wherein the active matrix substrate includes a non-display region located around the display region, and
the active matrix substrate further includes second TFTs provided in the non-display region and supported by the substrate, each of the second TFTs including a crystalline silicon semiconductor layer.

20. The active matrix substrate according to claim 19,
wherein each of the second TFTs includes a gate electrode provided on an insulating layer covering the crystalline silicon semiconductor layer, the gate electrode facing the crystalline silicon semiconductor layer with the insulating layer interposed between the gate electrode and the crystalline silicon semiconductor layer, and
the gate electrode of each of the second TFTs is formed in the same layer as the lower gate electrode of each of the first TFTS.

21. The active matrix substrate according to claim 1,
wherein the oxide semiconductor layer includes an In—Ga—Zn—O based semiconductor.

22. A liquid crystal display device comprising:
the active matrix substrate according to claim 1;
a counter substrate provided facing the active matrix substrate; and
a liquid crystal layer provided between the active matrix substrate and the counter substrate.
